(19) United States
(12) Patent Application Publication
(10) Pub. No.: US 2006/0223006 A1
(43) Pub. Date: Oct. 5, 2006

(54) Method of producing a planographic printing plate

(75) Inventors: Kazuto Shimada, Shizuoka (JP); Kazuto Kunita, Shizuoka (JP); Satoshi Hoshi, Shizuoka (JP)

Correspondence Address: BIRCH STEWART KOLASCH & BIRCH, PO BOX 747, FALLS CHURCH, VA, 22040-0747, US

(73) Assignee: FUJI PHOTO FILM CO., LTD.

(21) Appl. No.: 11/387,796

(22) Filed: Mar. 24, 2006

(30) Foreign Application Priority Data
Mar. 31, 2005 (JP) 2005-105246

(51) Int. Cl. G03F 7/00

(52) U.S. Cl. 430/302

(57) ABSTRACT

The method of producing the planographic printing plate of the present invention comprises forming a crosslinked hydrophilic layer on a substrate by hardening a hydrophilic polymer having a crosslinkable group at one terminal and a crosslinker by heat or light, and forming a hydrophobic image by ejecting an inkjet composition onto the formed crosslinked hydrophilic layer and by hardening the inkjet composition by heat or light.

### CROSS-REFERENCE TO RELATED APPLICATION

This application claims priority under 35 USC 119 from Japanese Patent Application No. 2005-105246, the disclosure of which is incorporated by reference herein.

### BACKGROUND OF THE INVENTION

1. Field of the Invention

The present invention relates to a method of producing a planographic printing plate, and in particular, to a method of producing a planographic printing plate having a superior hydrophilic surface that allows printing without the step of wet-process development treatment after image forming.

2. Description of the Related Art

Planographic printing is a printing method using a plate material which has an oleophilic region that accepts ink and an ink-repelling region (hydrophilic region) that accepts dampening water but not ink. Currently, photosensitive planographic printing plate precursors (PS plates) are widely used. PS plate, which has a photosensitive layer formed on a substrate such as an aluminum plate, have been commercialized and widely used. Such PS plates are used in printing, using the hydrophilicity of the substrate surface and the oleophilicity of the photosensitive layer formed in the image region after image exposure and removal of the photosensitive layer in the non-image region by development. There is a need for a plate material having a highly hydrophilic substrate surface for prevention of staining in the non-image region.

In a plate-making process using a conventional planographic printing plate precursor, a step of dissolving and removing the non-image region using a developing solution or the like according to the image recording layer is necessary after exposure to light, and elimination or simplification of such an additional wet-process treatment is mentioned as one of the issues to be resolved. In recent years, disposal of waste liquid discharged in the wet-process treatment has become a matter of high concern for the whole industry in consideration of the global environment, and therefore, demands for resolving the aforementioned issue have increased.

In response to these demands, a method called “in-machine development” has been proposed as an simple plate-making method in which an image recording layer from which a non-image region on a planographic printing plate precursor can be removed in an ordinary printing step is used for removing the non-image region in a printing machine after exposure to light to provide a planographic printing plate.

The specific method of in-machine development includes, for example, a method of using a planographic printing plate precursor having an image recording layer capable of being dissolved or dispersed in dampening water, an ink solvent or an emulsion of ink and dampening water, a method which involves physical removal of an image recording layer by contact with a roller or a blanket cylinder of a printing machine, and a method which involves physical removal of an image recording layer by contact with a roller or a blanket cylinder after weakening either the cohesive force of the image recording layer or the adhesion between the image recording layer and the substrate by permeation with dampening water, an ink solvent, or the like.

Unless otherwise noted, the term “development treatment step” in the present invention refers to a step wherein a region in a planographic printing plate precursor which has not been exposed to a beam from an infrared laser is removed by contact with a liquid (usually an alkaline developing solution) in an apparatus (usually an automatic developing machine) other than a printing machine to expose the surface of a hydrophilic substrate.

Further, the term “in-machine development” refers to a method and a process wherein a region which has not been exposed to a beam from an infrared laser in a planographic printing plate precursor is removed by contact with a liquid (usually printing ink and/or dampening water) in a printing machine to expose the surface of a hydrophilic substrate.

The development of lasers in recent years has been remarkable, and in particular, high-power, small-size solid lasers and semiconductor lasers emitting infrared beams at wavelengths of 760 to 1200 nm can be easily obtained. These infrared lasers are extremely useful as recording light sources for direct plate-making from the digital data from computers, and the like.

As the planographic printing plate precursors forming an image with the light from such a light source, planographic printing plate precursors have been proposed which, for example, comprise a hydrophilic substrate and an image-forming layer of hydrophobic thermoplastic polymer particles dispersed in a hydrophilic binder formed thereon (see, for example, Japanese Patent No. 2938397, Japanese Patent Application Laid-Open (JP-A) No. 9-127683 and WO No. 99/10186 Pamphlet). This planographic printing plate precursor can undergo in-machine development, wherein an image region is formed by exposure to an infrared laser such that hydrophobic thermoplastic polymer particles are fused by heat to form a hydrophilic region, the plate precursor is placed onto the cylinder of a printing machine, and the image is developed with dampening water and/or ink therein.

However, although this method of forming an image region simply by thermal fusion of fine particles shows effective in-machine development a certain extent, it is difficult to sufficiently remove the thermosensitive layer containing fine particles in the non-image region with dampening water or solvent ink, and thus, the method has the problems of residual thermosensitive layer components in the non-image region and staining in the non-image region during printing. The method also has problems that image intensity, in particular, the adhesiveness of an image region to a substrate, is extremely weak and printing durability is insufficient.

For the purpose of improving the hydrophilicity and durability of a printing plate precursor, a hydrophilic layer formed by hardening an acrylamide-hydroxyethyl acrylate copolymer with a methylol melamine crosslinker (see, for example, JP-A No. 2002-370467), a hydrophilic layer prepared by using gelatin or polyvinyl alcohol (see, for example, JP-A No. 11-95417), and a hydrophilic layer of a quaternary ammonium salt polymer (see, for example, Japanese Patent Application National-Phase Publication No. 2003-527978), and the like have been proposed. They have achieved improvements of the hydrophilicity of the polymer used and the crosslinked structure thereof to some extent, but they fail to provide a planographic printing plate precursor that is satisfactory from the viewpoints of staining during printing and ink repellency because they are insufficiently hydrophilic to use as a printing plate in practice.

Further, the hydrophilic layers formed above have insufficient hydrophilicity and durability, and thus, there were problems of background soil being easily generated depending on the printing conditions, and the non-image region became gradually stained as printing continued.

### SUMMARY OF THE INVENTION

The present invention has been made to solve the problems above. That is, the present invention provides a method of producing a planographic printing plate superior in hydrophilicity and durability of the non-image region and also in background soil resistance and ink repellency of the non-image region that allows printing without the step of development after image forming.

In a first aspect, the invention provides a method of producing a planographic printing plate, comprising: forming a crosslinked hydrophilic layer on a substrate by hardening a hydrophilic polymer having a crosslinkable group at one terminal and a crosslinker using heat or light, and forming a hydrophobic image by ejecting an inkjet composition onto the formed crosslinked hydrophilic layer and hardening the inkjet composition using heat or light.

In a second aspect, the invention provides the method of producing a planographic printing plate according to the first aspect, wherein the hydrophilic polymer contains, on a side chain, a plurality of hydrophilic functional groups including one or more kinds of hydrophilic functional groups selected from a carboxyl group, an amino group, a phosphoric acid group, a sulfonic acid group, salts of these groups, a hydroxyl group, an amide group, a sulfonamide group, an alkoxy group, a cyano group, and a polyoxyethylene group, and the like.

In a third aspect, the invention provides the method of producing a planographic printing plate according to the first aspect, wherein the hydrophilic polymer is a polymer having at least one heteroatom selected from oxygen, nitrogen, sulfur, or phosphorus connected to a carbon atom or carbon-carbon bond of the main chain or a polymer having, on the side chain, a plurality of hydrophilic functional groups including one or more kinds of hydrophilic functional groups selected from a carboxyl group, an amino group, a phosphoric acid group, a sulfonic acid group, salts of these groups, a hydroxyl group, an amide group, a sulfonamide group, an alkoxy group, a cyano group, and a polyoxyethylene group, and the like.

In a fourth aspect, the invention provides the method of producing a planographic printing plate according to the first aspect, wherein, in forming the crosslinked hydrophilic layer, a side-chain functional group of the hydrophilic polymer is different from the terminal crosslinkable group.

In a fifth aspect, the invention provides the method of producing a planographic printing plate according to the first aspect, wherein the hydrophilic polymer has a weight-average molecular weight of 1,000,000 or less.

In a sixth aspect, the invention provides the method of producing a planographic printing plate according to the first aspect, wherein the hydrophilic polymer has two or more crosslinkable groups on one terminal and the crosslinkable groups are different from each other.

In a seventh aspect, the invention provides the method of producing a planographic printing plate according to the first aspect, wherein a coloring agent is added to the crosslinked hydrophilic layer.

In an eighth aspect, the invention provides the method of producing a planographic printing plate according to the first aspect, wherein one or more crosslinkers are used in forming the crosslinked hydrophilic layer.

In a ninth aspect, the invention provides the method of producing a planographic printing plate, wherein at least two crosslinkers among the multiple crosslinkers react with each other, and at least one crosslinker has a functional group that forms a covalent bond and/or an ionic bond with the hydrophilic polymer having a crosslinkable group at one terminal.

In a tenth aspect, the invention provides the method of producing a planographic printing plate according to the first aspect, further comprising applying a coating solution containing the hydrophilic polymer and the crosslinker solubilized or dispersed in one or more solvents that are the same as or different from each other once or multiple times and then drying the coated solution.

In an eleventh aspect, the invention provides the method of producing a planographic printing plate according to the tenth aspect, wherein the drying is performed at 40° C. to 300° C.

In a twelfth aspect, the invention provides the method of producing a planographic printing plate according to the first aspect, wherein the inkjet composition comprises a polymerization-initiating system containing a polymerization initiator and a sensitization coloring agent, and polymerizable compounds containing a radically polymerizable compound and a cationically polymerizable compound.

In a thirteenth aspect, the invention provides the method of producing a planographic printing plate according to the twelfth aspect, wherein one or more compounds selected from the group consisting of aromatic ketones, aromatic onium salt compounds, organic peroxides, hexaarylbiimidazole compounds, ketoxime ester compounds, borate compounds, azinium compounds, metallocene compounds, active ester compounds, and compounds having a carbon-halogen bond are used as the polymerization initiator.

In a fourteenth aspect, the invention provides the method of producing a planographic printing plate according to the twelfth aspect, wherein a coloring agent is used in the inkjet composition.

In a fifteenth aspect, the invention provides the method of producing a planographic printing plate according to the twelfth or fourteenth aspect, wherein the content of the coloring agent in the inkjet composition is 1 to 10 wt %; that of the polymerizable compound is 1 to 97 wt %; and that of the polymerization-initiating system is 0.01 to 20 wt % based on the weight of the inkjet composition.

In a sixteenth aspect, the invention provides the method of producing a planographic printing plate according to the first aspect, wherein the ratio of the components in the inkjet composition is adjusted such that the composition has a viscosity in the range of 7 to 30 m Pa·s.

In a seventeenth aspect, the invention provides the method of producing a planographic printing plate according to the first aspect, wherein the surface tension of the inkjet composition is 20 to 30 mN/m.

### DETAILED DESCRIPTION OF THE INVENTION

The method of producing the planographic printing plate according to the present invention comprises (1) a step of forming a crosslinked hydrophilic layer on a substrate by hardening a hydrophilic polymer having a crosslinkable group at one terminal and a crosslinker using heat or light (hereinafter, referred to as crosslinked hydrophilic layer-forming step), and (2) a step of forming a hydrophobic image by ejecting an inkjet composition onto the formed crosslinked hydrophilic layer and hardening the inkjet composition by heat or light (hereinafter, referred to as image region forming step).

Hereinafter, the inventive method will be descried in the order of the steps.

[A Step of Forming a Crosslinked Hydrophilic Layer on a Substrate by Hardening a Hydrophilic Polymer Having a Crosslinkable Group at One Terminal and a Crosslinker by Heat or Light]

In this step, i.e., in the crosslinked hydrophilic layer-forming step, a crosslinked hydrophilic layer-forming composition which comprises (A) a hydrophilic polymer having a crosslinkable group at one terminal and (B) a crosslinker is applied on a substrate, and the coated film is hardened by heat or light, to form a crosslinked hydrophilic layer. Components contained in the crosslinked hydrophilic layer-forming composition will be described below.

<(A) Hydrophilic Polymer Having a Crosslinkable Group at One Terminal>

The hydrophilic polymer having a crosslinkable group at one terminal for use in the invention is not particularly limited, if it has at one terminal a functional group reactive with a known thermal crosslinker and becomes water-insoluble in reaction with the crosslinker. Examples of the known thermal crosslinkers include those described in “Crosslinker Handbook”, by Shinzo Yamashita and Tosuke Kaneko, published by Taiseisha Co., Ltd (1981). Examples of the functional groups reactive with the crosslinker include a carboxyl group or salts thereof; anhydrous carboxylic acid, amino, hydroxyl, epoxy, methylol, mercapto, (blocked) isocyanate, silanol (silane-coupling), carbon-carbon double bond, ester, and tetrazole groups; radically polymerizable groups such as acrylate, methacrylate, and styryl; and the like.

The hydrophilic polymer is a polymer having, on a side chain, a plurality of hydrophilic functional groups including one or more kinds of hydrophilic functional groups selected from a carboxyl group, an amino group, a phosphoric acid group, a sulfonic acid group, salts of these groups, a hydroxyl group, an amide group, a sulfonamide group, an alkoxy group, a cyano group, and a polyoxyethylene group, and the like, or a polymer having at least one heteroatom selected from oxygen, nitrogen, sulfur, or phosphorus connected to a carbon atom or the carbon-carbon bonds in the main chain or a polymer having, on a side chain, a plurality of hydrophilic functional groups including one or more kinds of hydrophilic functional groups selected from a carboxyl group, an amino group, a phosphoric acid group, a sulfonic acid group, salts of these groups, a hydroxyl group, an amide group, a sulfonamide group, an alkoxy group, a cyano group, and a polyoxyethylene group, and the like.

The side-chain functional group of the hydrophilic polymer is preferably different from the terminal crosslinkable group, in order to crosslink only the terminal of the hydrophilic polymer when forming the crosslinked hydrophilic layer, and more preferably, the terminal crosslinkable group is higher in crosslinking reactivity than the side-chain functional group.

The hydrophilic polymer having a crosslinkable group at one terminal in the invention can be prepared according to any one of known methods. For example, it can be prepared by radically polymerizing a hydrophilic monomer such as acrylamide, acrylic acid, or 3-sulfopropyl methacrylate potassium salt in the presence of a chain transfer such as 3-mercaptopropionic acid, 2-aminoethanethiol hydrochloride, 3-mercaptopropanol, 2-hydroxyethyldisulfide, or a compound described in Radical Polymerization Handbook (NTS Book Co., Ltd., Kanji Uraike and Tsuyoshi Endo) or an iniferter such as that described in Macromolecules 1986, 19, p. 287 (Otsu), or radically polymerizing a hydrophilic monomer such as acrylamide by using a radical polymerization initiator having a crosslinkable group such as a carboxyl group instead of a chain transfer. The radical polymerization method of using a chain transfer is preferable, from the viewpoint of control of the molecular weight of the desirable polymer.

Typical examples of the hydrophilic polymers having a crosslinkable group at one terminal include the compounds below. The number shown in each structural unit is a polymerization degree of the structural unit.

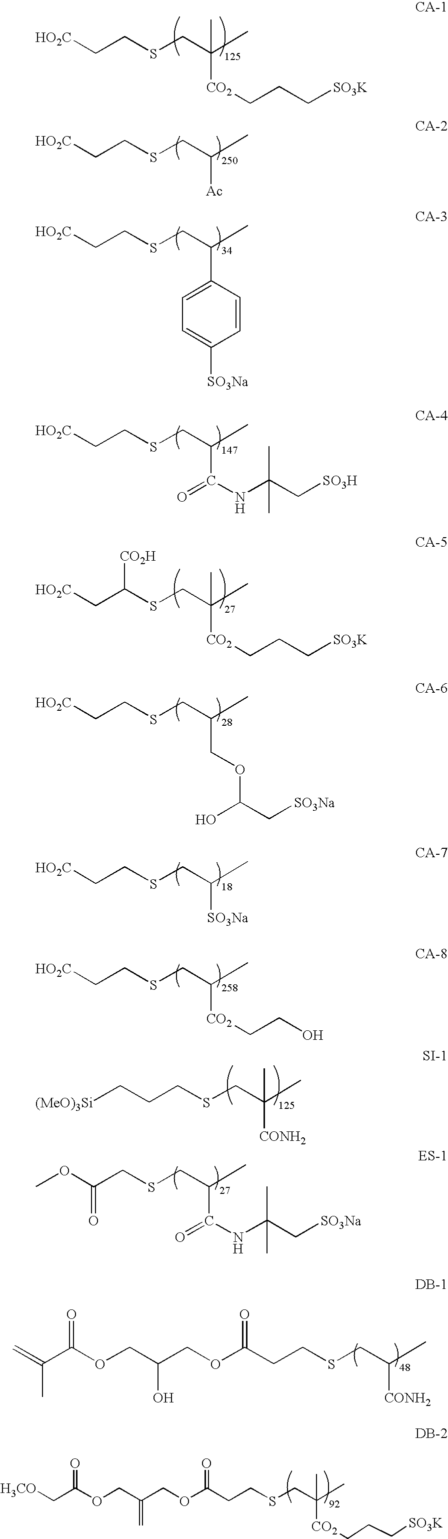

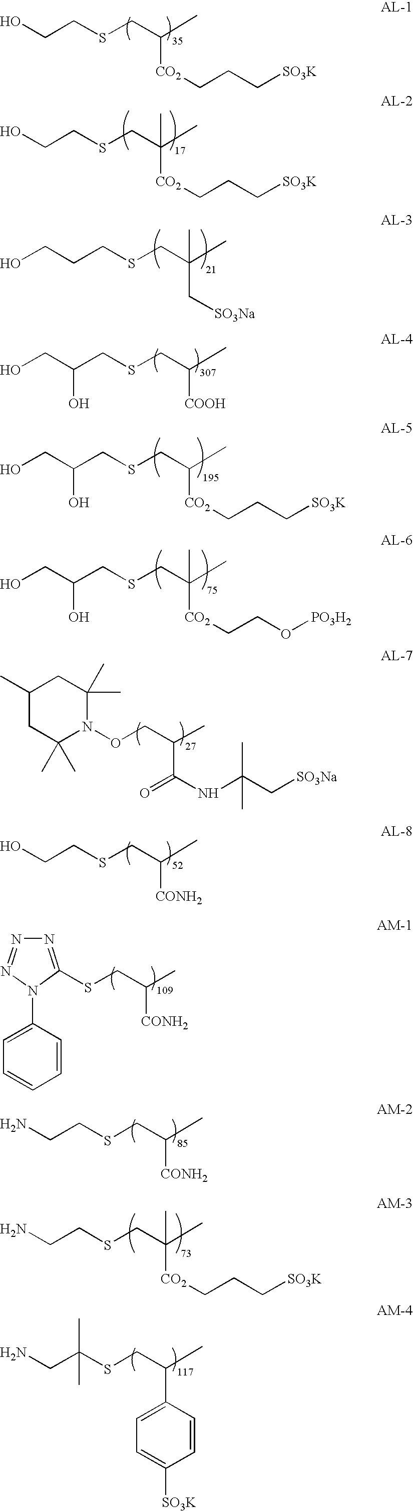

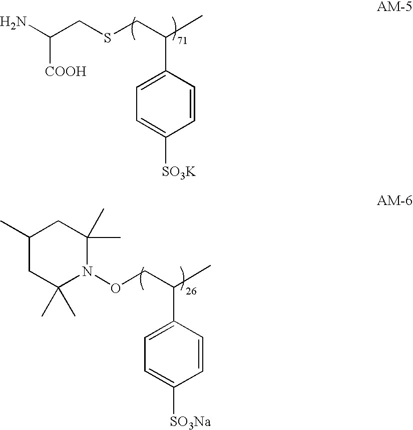

In addition, the following polymers containing a radically polymerizable group may also be used as the hydrophilic polymer having a crosslinkable group at one terminal in the invention.

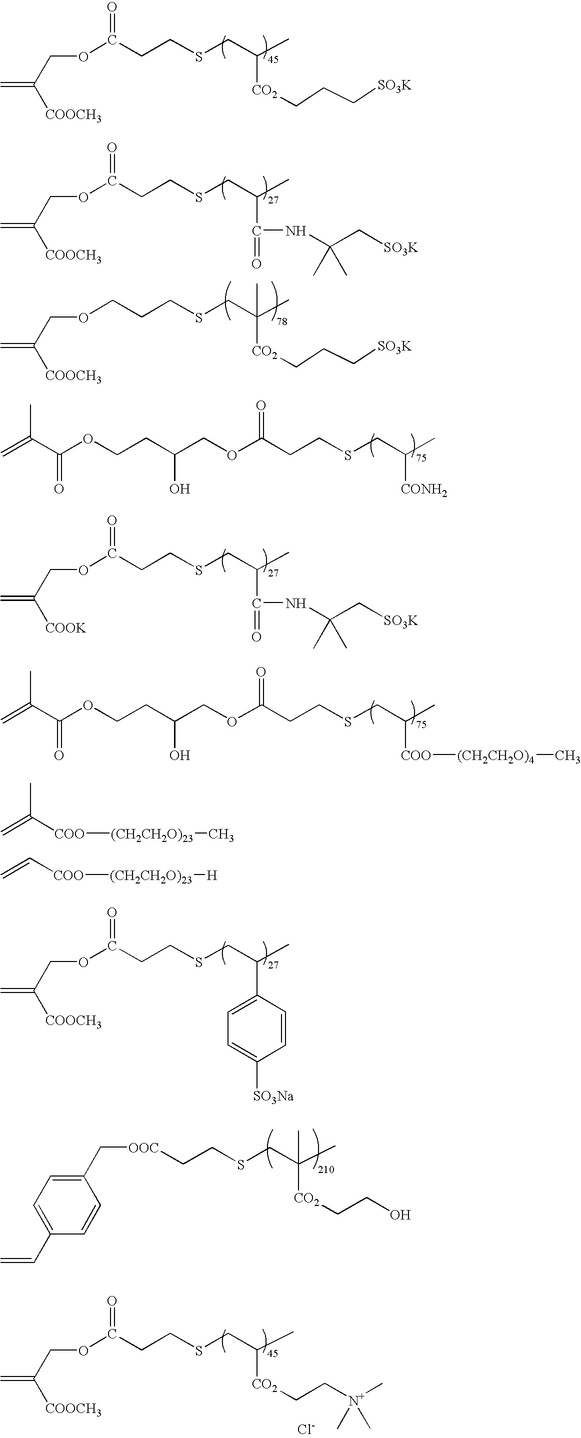

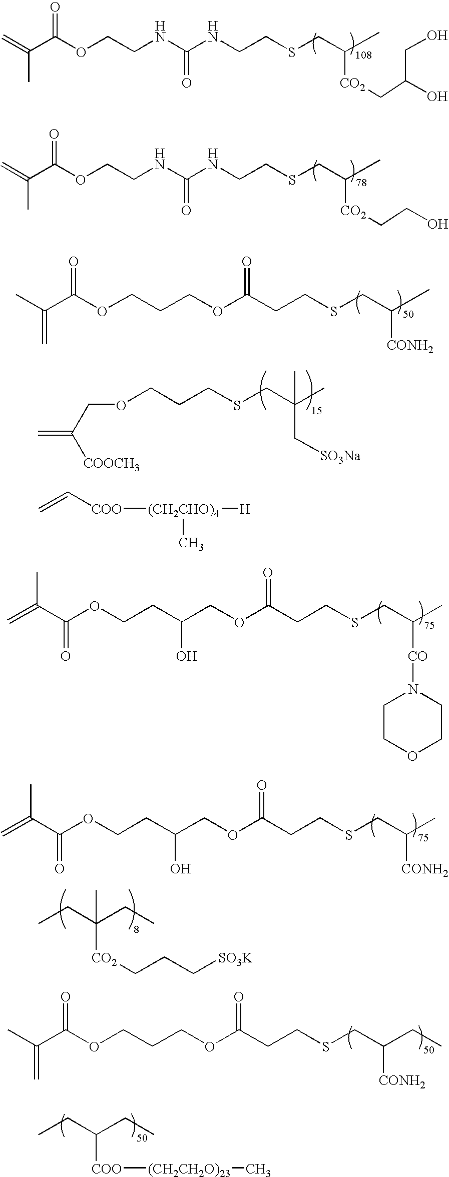

The hydrophilic polymer preferably has a weight average molecular weight of 1,000,000 or less, more preferably in the range of 1,000 to 1,000,000, and still more preferably 10,000 to 70,000. A polymer having a molecular weight of more than 1,000,000 may cause problems in handling, because it becomes less soluble in solvent during preparation of coating solutions, raises the viscosity of the coating solution and does not give a uniform film easily, and is thus undesirable.

The polymer may have two or more crosslinkable groups at one terminal, and further, two or more different crosslinkable groups at one terminal.

In the invention, the content of the hydrophilic polymer (A) having a crosslinkable group at one terminal in the crosslinked hydrophilic layer-forming composition may be selected properly according to applications, but is generally, preferably 10 to 95 wt % and more preferably 45 to 90 wt %.

<(B) Crosslinker>

Any one of known thermally crosslinkable crosslinkers may be used as the crosslinker for use in the invention. Common thermal crosslinkers include those described in Shinzo Yamashita and Tosuke Kaneko, “Crosslinker Handbook”, published by Taiseisha Co., Ltd. (1981). The crosslinker for use in the invention is not particularly limited, if it has two or more functional groups and is effective in crosslinking the hydrophilic polymer. Typical examples of the thermal crosslinkers include α,ω-alkane- or alkene-dicarboxylic acids such as 1,2-ethanedicarboxylic acid and adipic acid; polycarboxylic acids such as 1,2,3-propanetricarboxylic acid, 1,2,3,4-butanetetracarboxylic acid, trimellitic acid, and polyacrylic acid; amine compounds such as butylamine, spermine, diaminecyclohexane, piperazine, aniline, phenylenediamine, 1,2-ethanediamine, diethylenediamine, diethylenetriamine, and polyethyleneimine; polyepoxy compounds such as ethylene or propylene glycol diglycidylether, tetraethylene glycol diglycidylether, nonaethylene glycol diglycidylether, polyethylene or polypropylene glycol glycidylether, neopentylglycol diglycidylether, 1,6-hexanediol diglycidylether, trimethylolpropane triglycidylether, and sorbitol polyglycidylether; oligoalkylene or polyalkylene glycols such as ethylene glycol, propylene glycol, diethylene glycol, and tetraethylene glycol; polyhydroxy compounds such as trimethylolpropane, glycerol, pentaerythritol, sorbitol, and polyvinylalcohol; polyaldehyde compounds such as glyoxal and terephthalaldehyde; polyisocyanate compounds such as tolylene diisocyanate, hexamethylene diisocyanate, diphenylmethane isocyanate, xylylene diisocyanate, polymethylene polyphenyl isocyanate, cyclohexyl diisocyanate, cyclohexane phenylene diisocyanate, naphthalene-1,5-diisocyanate, isopropylbenzene-2,4-diisocyanate, and polypropylene glycol/tolylene diisocyanate adducts; blocked polyisocyanate compounds; silane-coupling agents such as tetraalkoxysilane; metal crosslinkers such as acetylacetonates of aluminum, copper, and iron (III); polymethylol compounds such as trimethylol melamine and pentaerythritol; polythiol compounds such as dithioerythritol, pentaerythritol tetrakis(2-mercaptoacetate), and trimethylolpropane tris(2-mercaptoacetate); and the like.

Among these thermal crosslinkers, water-soluble crosslinkers are preferable from the viewpoints of easier in the preparation of coating solution and preventing deterioration in hydrophilicity of the hydrophilic materials prepared.

When the crosslinked hydrophilic layer in the invention is formed by radical hardening, a radically polymerizable compound may be used as the crosslinking component. The radically polymerizable compound is an addition polymerizable compound having at least one ethylenic unsaturated double bond, and is selected from compounds having at least one, preferably two or more, terminal ethylenically unsaturated bond.

A group of such compounds is known widely in this industrial field, and in the invention, these compounds is not particularly limited. These compounds occur in chemical forms such as monomers, prepolymers, that is, dimers, trimers and oligomers, as well as mixtures and copolymers thereof.

Examples of such monomers and copolymers include unsaturated carboxylic acids (e.g., acrylic acid, methacrylic acid, itaconic acid, crotonic acid, isocrotonic acid, maleic acid, etc.) and esters and amides thereof. Among these compounds, esters between unsaturated carboxylic acids and aliphatic polyvalent alcohols and amides between unsaturated carboxylic acids and aliphatic polyvalent amines are preferable. Also, addition reaction products of unsaturated carboxylic esters or amides having nucleophilic substituent groups such as hydroxyl group, amino group, mercapto group, or the like with monofunctional or multifunctional isocyanates or with epoxy compounds, and dehydration condensation reaction products of unsaturated carboxylic esters or amides having nucleophilic substituent groups such as hydroxyl group, amino group, mercapto group, or the like with monofunctional or multifunctional carboxylic acids are preferably used. Further, addition reaction products of unsaturated carboxylic esters or amides having electrophilic substituent groups such as isocyanate group, epoxy group, or the like, with monofunctional or multifunctional alcohols, amines or thiols, substitution reaction products of unsaturated carboxylic esters or amides having leaving group substituent such as halogen, tosyloxy group, or the like with monofunctional or multifunctional alcohols, amines or thiols, and the like are also used. Alternatively, a group of those compounds wherein the above-described carboxylic acids are replaced with unsaturated phosphonic acids, styrene, vinyl ethers, or the like may be also used.

Specific examples of the ester monomers of aliphatic polyvalent alcohols and unsaturated carboxylic acids include as follows;

Examples of the acrylates include ethylene glycol diacrylate, triethylene glycol diacrylate, 1,3-butane diol diacrylate, tetramethylene glycol diacrylate, propylene glycol diacrylate, neopentyl glycol diacrylate, trimethylol propane triacrylate, trimethylol propane tri(acryloyloxypropyl)ether, trimethylol ethane triacrylate, hexane diol diacrylate, 1,4-cyclohexane diol diacrylate, tetraethylene glycol diacrylate, pentaerythritol diacrylate, pentaerythritol triacrylate, pentaerythritol tetracrylate, dipentaerythritol diacrylate, dipentaerythritol hexacrylate, sorbitol triacrylate, sorbitol tetracrylate, sorbitol pentacrylate, sorbitol hexacrylate, tri(acryloyloxyethyl) isocyanurate, polyester acrylate oligomers, ethyleneoxide-modified isocyanuric acid triacrylate, and the like.

Examples of the methacrylates include tetramethylene glycol dimethacrylate, triethylene glycol dimethacrylate, neopentyl glycol dimethacrylate, trimethylol propane trimethacrylate, trimethylol ethane trimethacrylate, ethylene glycol dimethacrylate, 1,3-butane diol dimethacrylate, hexane diol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethyl methane, bis[p-(methacryloxyethoxy)phenyl]dimethyl methane, and the like.

Examples of the itaconates include ethylene glycol diitaconate, propylene glycol diitaconate, 1,3-butane diol diitaconate, 1,4-butane diol diitaconate, tetramethylene glycol diitaconate, pentaerythritol diitaconate, sorbitol tetraitaconate, etc. Examples of the crotonates include ethylene glycol dicrotonate, tetramethylene glycol dicrotonate, pentaerythritol dicrotonate, sorbitol tetradicrotonate, and the like.

Examples of the isocrotonates include ethylene glycol diisocrotonate, pentaerythritol diisocrotonate, sorbitol tetraisocrotonate, and the like. Examples of the maleates include ethylene glycol dimaleate, triethylene glycol dimaleate, pentaerythritol dimaleate, sorbitol tetramaleate, and the like.

Examples of other preferably used esters include aliphatic alcohol-based esters described in JP-B No. 51-47334, and JP-A No. 57-196231, those having an aromatic skeleton described in JP-A Nos. 59-5240, 59-5241 and 2-226149, and those having an amino group described in JP-A No. 1-165613. The ester monomers can also be used as a mixture.

Examples of the amide monomers of aliphatic polyvalent amine compounds and unsaturated carboxylic acids include methylene bis-acrylamide, methylene bis-methacrylamide, 1,6-hexamethylene bis-acrylamide, 1,6-hexamethylene bis-methacrylamide, diethylene triamine trisacrylamide, xylylene bisacrylamide, xylylene bismethacrylamide, and the like. Preferable examples of other amide based monomers include those having a cyclohexylene structure described in JP-B 54-21726.

Urethane based addition polymerizable compounds produced by addition reaction of isocyanate and hydroxyl groups are also preferable, and examples thereof include vinyl urethane compounds containing two or more polymerizable vinyl groups in one molecule, which are prepared by adding vinyl monomers containing a hydroxyl group shown in formula (II) below to polyisocyanate compounds having two or more isocyanate groups in one molecule as described in JP-B 48-41708.
CH₂═C(R⁴)COOCH₂CH(R⁵)OH (II)
wherein, R⁴and R⁵ each independently represent H or CH_{3.}

Urethane acrylates described in JP-A No. 51-37193, JP-B No. 2-32293 and JP-B No. 2-16765 and urethane compounds having an ethylene oxide based skeleton described in JP-B No. 58-49860, JP-B No. 56-17654, JP-B No. 62-39417 and JP-B No. 62-39418 are also preferable. Further, addition polymerizable compounds having an amino or sulfide structure in the molecule as described in JP-A Nos. 63-277653, 63-260909 and 1-105238 can be used to prepare photopolymerizable compositions extremely excellent in photosensitizing speed.

Other examples include multifunctional acrylates and methacrylates such as polyesteracrylates, and epoxy acrylates obtained by reacting epoxy resin with (meth)acrylic acid as described in JP-A No. 48-64183, JP-B No. 49-43191 and JP-B No. 52-30490. Further, specific unsaturated compounds described in JP-B No. 46-43946, JP-B No. 1-40337 and JP-B No. 1-40336, and vinyl phosphonic acid-based compounds described in JP-A No. 2-25493 can also be mentioned. In some cases, a structure containing a perfluoroalkyl group described in JP-A 61-22048 is preferably used. Photocurable monomers and oligomers described in the Journal of The Adhesion Society of Japan, vol. 20, No. 7, pp. 300-308 (1984) can also be used.

Alternatively, a crosslinker that can be ionically bond to the hydrophilic polymer (A) having a crosslinkable group at one terminal may be used. For example, a multifunctional amine can be used as a crosslinker (B) when the terminal of the specific hydrophilic polymer (A) is carboxylic acid, while a carboxylic acid can be used as a crosslinker (B), when the terminal of the specific hydrophilic polymer (A) is amine.

[Combination of the Hydrophilic Polymer (A) Having a Crosslinkable Group at One Terminal and Crosslinker (B)]

Favorable combinations of the crosslinkable group in the hydrophilic polymer (A) having a crosslinkable group at one terminal and the crosslinker (B) for use in the invention include the followings:

A hydrophilic polymer having, at one terminal, a carboxyl group or the salt thereof can forms a three-dimensionally crosslinked network with the polyepoxy compound, polyamine compound, polymethylol compound, polyisocyanate compound, blocked polyisocyanate compound, or metal crosslinker described above.

A hydrophilic polymer having a methylol, phenolic hydroxyl, or glycidyl group at one terminal may forms a three-dimensionally crosslinked network, with the polycarboxylic acid compound, polyamine compound or polyhydroxy compound described above as a crosslinker.

A hydrophilic polymer having an amino group at one terminal may forms a three-dimensionally crosslinked network with the polyisocyanate compound or blocked polyisocyanate compound, polyepoxy compound, or polymethylol compound as a crosslinker.

A hydrophilic polymer having a hydroxyl group at one terminal may forms a three-dimensionally crosslinked network with the polyisocyanate or blocked polyisocyanate compound, polyaldehyde compound, polycarboxylic acid compound, or polyepoxy compound described above as a crosslinker.

A hydrophilic polymer having a silane coupling group such as alkoxysilyl group at one terminal may forms a three-dimensionally crosslinked network by dehydration condensation with a tetraalkoxysilane, a polyvalent alcohol, or the like.

A hydrophilic polymer having a carbon-carbon double bond at one terminal may forms a three-dimensionally crosslinked network, with a polythiol compound such as dithioerythritol, pentaerythritol tetrakis(2-mercaptoacetate), or trimethylolpropane tris(2-mercaptoacetate), an amine compound such as butylamine, spermine, diaminecyclohexane, piperazine, aniline, phenylenediamine, 1,2-ethanediamine, diethylenediamine, diethylenetriamine, or polyethyleneimine, or the like as a crosslinker.

In addition, a multifunctional radically polymerizable crosslinker and a terminal radically polymerizable hydrophilic polymer may also be used in combination.

When only one kind of crosslinker is used, the crosslinker is preferably trifunctional or higher, and it is preferable to react between the crosslinkers. Such crosslinkers include, for example, multifunctional epoxy compounds.

One of the crosslinkers (B) may be used alone or two or more of the crosslinkers may be used in combination. When two or more crosslinkers, for example two kinds of crosslinkers, (B-1) and (B-2), are used, preferably, one crosslinker (B-1) is bifunctional or higher, and the other crosslinker (B-2) is trifunctional or higher; and when the crosslinker (B-1) is bifunctional or higher, at least one functional group of crosslinker (B-1) is preferably reactive both with the crosslinkable group present in the terminal crosslinkable hydrophilic polymer (A) and with the crosslinker (B-2), and at least one other functional group in the crosslinker (B-1) preferably has a functional group reactive with the crosslinker (B-2).

The crosslinker (B-2) is preferably reactive both with the crosslinkable group in the terminal crosslinkable hydrophilic polymer (A) and with the crosslinker (B-1), or only with the crosslinker (B-1). The crosslinker (B-2) reacts only with the crosslinker (B-1), for example, when the crosslinkable group in the terminal crosslinkable hydrophilic polymer (A) and that of the crosslinker (B-2) are of the same kind.

In a preferable embodiment, at least two kinds of crosslinkers among a plurality of the crosslinkers are reactive with each other, and at least one kind of crosslinker among a plurality of the crosslinkers has a functional group that may forms a covalent bond with the hydrophilic polymer having a crosslinkable group at one terminal, from the viewpoint of film-forming efficiency.

In the invention, the content of the crosslinker (B) in the crosslinked hydrophilic layer-forming composition may be selected appropriately according to the purpose of application, but is preferably 5 to 95 wt %, more preferably 10 to 50 wt %, based on the solid content.

In a favorable combination of polymer (A) and crosslinker (B), the polymer (A) has, at one terminal, a carboxylic acid, a hydroxyl group, or amine group, and the crosslinker (B) is a multifunctional epoxy compound or a multifunctional carboxylic acid. Alternatively, a combination of a multifunctional amine compound and a multifunctional carboxylic acid is also favorable.

<Surfactant>

In the invention, a surfactant is used preferably in the crosslinked hydrophilic layer in order to promote in-machine developability upon initiation of printing and to improve the coated surface property. Examples of the surfactant include a nonionic surfactant, anionic surfactant, cationic surfactant, amphoteric surfactant and fluorine-based surfactant. One of the surfactants may be used alone or two or more thereof may be used in combination.

The nonionic surfactant used in the invention is not particularly limited, and a conventionally known nonionic surfactant can be used. Examples of the nonionic surfactant include polyoxyethylene alkyl ethers, polyoxyethylene alkyl phenyl ethers, polyoxyethylene polystyryl phenyl ethers, polyoxyethylene polyoxypropylene alkyl ethers, partial esters of glycerin with fatty acid, partial esters of sorbitan with fatty acid, partial esters of pentaerythritol with fatty acid, esters of propylene glycol with monofatty acid, partial esters of sucrose with fatty acid, partial esters of polyoxyethylene sorbitan with fatty acid, polyethylene glycol fatty acid esters, partial esters of polyglycerin with fatty acid, polyoxyethylene castor oil, partial esters of polyoxyethylene glycerin with fatty acid, fatty acid diethanol amides, N,N-bis-2-hydroxyalkyl amines, polyoxyethylene alkyl amine, triethanol amine fatty acid ester, trialkyl amine oxide, polyethylene glycol, and a polyethylene glycol/polypropylene glycol copolymer.

The anionic surfactant used in the invention is not particularly limited, and a conventionally known anionic surfactant can be used. Examples of the anionic surfactant include aliphatic acid salts, abietates, hydroxyalkane sulfonates, alkane sulfonates, dialkylsulfosuccinates, linear alkyl benzene sulfonates, branched alkyl benzene sulfonates, alkyl naphthalene sulfonates, alkyl phenoxy polyoxyethylene propyl sulfonates, polyoxyethylene alkyl sulfophenyl ether salts, sodium N-methyl-N-oleyl taurates, disodium N-alkyl sulfosuccinic monoamide salt, petroleum sulfonates, sulfuric acid tallow oil, fatty alkyl sulfates, alkyl sulfates, polyoxyethylene alkyl ether sulfates, fatty monoglyceride sulfates, polyoxyethylene alkyl phenyl ether sulfates, polyoxyethylene styryl phenyl ether sulfates, alkyl phosphates, polyoxyethylene alkyl ether phosphates, polyoxyethylene alkyl phenyl ether phosphates, partially saponified styrene/maleic anhydride copolymers, partially saponified olefin/maleic anhydride copolymers and condensates of naphthalene sulfonate and formalin.

The cationic surfactant used in the invention is not particularly limited, and a conventionally known cationic surfactant can be used. Examples of the cationic surfactant include alkyl amine salts, quaternary ammonium salts, polyoxyethylene alkyl amine salts and polyethylene polyamine derivatives.

The amphoteric surfactant used in the invention is not particularly limited, and a conventionally known amphoteric surfactant can be used. Examples of the amphoteric surfactant include carboxy betaines, aminocarboxylic acids, sulfobetaines, aminosulfates and imidazolines.

The term “polyoxyethylene” in the surfactants described above can be read as “polyoxyalkylene” such as polyoxymethylene, polyoxypropylene, polyoxybutylene, etc., and these surfactants can also be used in the invention.

Further preferable surfactants are fluorine-based surfactants containing a perfluoroalkyl group in their molecule. Such fluorine-based surfactants include anionic surfactants such as perfluoroalkyl carboxylates, perfluoroalkyl sulfonates and perfluoroalkyl phosphates, amphoteric surfactants such as perfluoroalkyl betaine, cationic surfactants such as perfluoroalkyl trimethyl ammonium salts, and nonionic surfactants such as perfluoroalkyl amine oxide, perfluoroalkyl ethylene oxide adducts, perfluoroalkyl group- or hydrophilic group-containing oligomers, perfluoroalkyl group- or lipophilic group-containing oligomers, perfluoroalkyl group-, hydrophilic group- or lipophilic group-containing oligomers, and perfluoroalkyl group- or lipophilic group-containing urethane. Preferable examples also include fluorine-based surfactants described in JP-A Nos. 62-170950, 62-226143 and 60-168144.

The surfactants can be used alone or two or more thereof can be used in combination.

The content of surfactant is preferably in an amount of 0.001 to 10% by weight, and more preferably 0.01 to 5% by weight, based on the total solid content of the image recording layer.

<Coloring Agent>

To the crosslinked hydrophilic layer in the invention, various compounds other than the above-mentioned compounds may be added if necessary. For example, dyes having large absorption band in the visible spectrum can be used as coloring agents for images.

Specific examples thereof include Oil Yellow #101, Oil Yellow #103, Oil Pink #312, Oil Green BG, Oil Blue BOS, Oil Blue #603, Oil Black BY, Oil Black BS, Oil Black T-505 (which are available from Orient Chemical Industries, Ltd.), Victoria Pure Blue, Crystal Violet (CI42555), Methyl Violet (CI42535), Ethyl Violet, Rhodamine B (CI145170B), Malachite Green (CI42000), Methylene Blue (CI52015), and dyes described in JP-A No. 62-293247. Pigments such as phthalocyanine pigment, azo pigment, carbon black and titanium oxide can also be preferably used.

Such a coloring agent is preferably added to the crosslinked hydrophilic layer in order to distinguish the image region from the non-image region after image formation. An amount of the coloring agent added is preferably 0.01 to 10% by weight based on the total solid content of the image recording layer.

<Printing-Out Agent>

A compound which becomes discolored due to an acid or radical can be added to the crosslinked hydrophilic layer to form an image printed out. Examples of such compound include various dyes such as diphenyl methane, triphenyl methane, thiazine, oxazine, xanthene, anthraquinone, iminoquinone, azo, azomethine dyes, and the like.

Specific examples thereof include dyes such as Brilliant Green, Ethyl Violet, Methyl Green, Crystal Violet, Basic Fuchsin, Methyl Violet 2B, Quinaldine Red, Rose Bengal, Metanil Yellow, Thymol Sulfophthalein, Xylenol Blue, Methyl Orange, Paramethyl Red, Congo Red, Benzopulpurine 4B, α-Naphthyl Red, Nile Blue 2B, Nile Blue A, Methyl Violet, Malachite Green, Parafuchsin, Victoria Pure Blue BOH [manufactured by Hodogaya Kagaku Co., Ltd.], Oil Blue #603 [manufactured by Orient Chemical Industries, Ltd.], Oil Pink #312 [manufactured by Orient Chemical Industries, Ltd.], Oil Red 5B [manufactured by Orient Chemical Industries, Ltd.], Oil Scarlet #308 [manufactured by Orient Chemical Industries, Ltd.], Oil Red OG [manufactured by Orient Chemical Industries, Ltd.], Oil Red RR [manufactured by Orient Chemical Industries, Ltd.], Oil Green #502 [manufactured by Orient Chemical Industries, Ltd.], Spiron Red BEH Special [manufactured by Hodogaya Kagaku Co., Ltd.], m-Cresol Purple, Cresol Red, Rhodamine B, Rhodamine 6G, Sulforhodamine B, Auramine, 4-p-diethylaminophenyl iminonaphthoquinone, 2-carboxyanilino-4-p-diethylaminophenyl iminonaphthoquinone, 2-carboxystearylamino-4-p-N,N-bis(hydroxyethyl) amino-phenyliminonaphthoquinone, 1-phenyl-3-methyl-4-p-diethylaminophenylimino-5-pyrazolone and 1-β-naphthyl-4-p-diethylaminophenylimino-5-pyrazolone, and leuco dyes such as p,p′,p″-hexamethyl triaminotriphenyl methane (Leuco Crystal Violet) and Pergascript Blue SRB (manufactured by Ciba-Geigy).

In addition, leuco dyes known as material of thermal sensitive paper and pressure sensitive paper can be preferably used. Specific examples of the leuco dyes include crystal violet lactone, malachite green lactone, benzoyl leucomethylene blue, 2-(N-phenyl-N-methylamino)-6-(N-p-tolyl-N-ethyl)amino-fluoran, 2-anilino-3-methyl-6-(N-ethyl-p-toluidino)fluoran, 3,6-dimethoxy fluoran, 3-(N,N-diethylamino)-5-methyl-7-(N,N-dibenzylamino)-fluoran, 3-(N-cyclohexyl-N-methylamino)-6-methyl-7-anilinofluoran, 3-(N,N-diethylamino)-6-methyl-7-anilinofluoran, 3-(N,N-diethylamino)-6-methyl-7-xylidinofluoran, 3-(N,N-diethylamino)-6-methyl-7-chlorofluoran, 3-(N,N-diethylamino)-6-methoxy-7-aminofluoran, 3-(N,N-diethylamino)-7-(4-chloroanilino)fluoran, 3-(N,N-diethylamino)-7-chlorofluoran, 3-(N,N-diethylamino)-7-benzyl aminofluoran, 3-(N,N-diethylamino)-7,8-benzofluoran, 3-(N,N-dibutylamino)-6-methyl-7-anilinofluoran, 3-(N,N-dibutylamino)-6-methyl-7-xylidinofluoran, 3-piperidino-6-methyl-7-anilinofluoran, 3-pyrrolidino-6-methyl-7-anilinofluoran, 3,3-bis(1-ethyl-2-methylindol-3-yl)phthalide, 3,3-bis(1-n-butyl-2-methylindol-3-yl) phthalide, 3,3-bis(p-dimethylaminophenyl)-6-dimethyl amino phthalide, 3-(4-diethylamino-2-ethoxyphenyl)-3-(1-ethyl-2-methylindol-3-yl)-4-azaphthalide, 3-(4-diethylaminophenyl)-3-(1-ethyl-2-methylindol-3-yl) phthalide, and the like.

An addition amount of the dye that is discolored due to acid or radical is 0.01 to 10% by weight based on the solid content of the image recording layer.

<Formation of the Crosslinked Hydrophilic Layer>

The crosslinked hydrophilic layer in the invention may be formed by dispersing or dissolving the necessary components described above in a solvent to prepare a coating solution and then applying the coating solution. Examples of the solvent to be used include, but are not limited to, ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethylacetamide, N,N-dimethylformamide, tetramethyl urea, N-methyl pyrrolidone, dimethyl sulfoxide, sulfolane, y-butyrolactone, toluene and water. These solvents are used alone or a mixture thereof may be used. The solid content in the coating solution is preferably 1 to 50% by weight.

Alternatively, the crosslinked hydrophilic layer can be formed by dispersing or dissolving the same or different components described above in the same or different solvents to obtain a plurality of coating solutions and then applying and drying the solutions repeatedly several times.

The preferable coating amount (solid content) of the crosslinked hydrophilic layer on a substrate, which is obtained after coating and drying, varies depending on applications, but is preferably 0.1 to 10.0 g/m², preferably 0.3 to 7.0 g/m², and more preferably 0.5 to 5.0 g/m². In the coating amount of this range described above, a film having good hydrophilicity and excellent strength can be obtained.

For coating, various methods can be used as necessary. Examples of the coating method include bar coating, rotational coating, spray coating, curtain coating, dip coating, air knife coating, blade coating and roll coating.

Drying after application of the coating solution accelerates the crosslinking reaction, thereby forming a crosslinked hydrophilic layer. The temperature condition during thermal crosslinking is not particularly limited, but the temperature is preferably in the range of 40° C. to 300° C. and more preferably 60° C. to 250° C., from the viewpoints of crosslinking efficiency and stability of production.

<Substrate>

The substrate used in the planographic printing plate of the invention is not particularly limited insofar as it is a dimensionally stable plate. Examples thereof include paper, paper laminated with plastics such as polyethylene, polypropylene, polystyrene and the like, a metal plate such as aluminum, zinc, copper, and the like, a plastic film such as cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate, polyvinyl acetal, and the like, and paper or a plastic film on which the above-described metal is laminated or vapor-deposited. The substrate is preferably a polyester film or an aluminum plate. Especially, the aluminum plate is particularly preferable because it is superior in dimensional stability and relatively inexpensive.

The thickness of the substrate is preferably about 0.05 to 1.0 mm, more preferably 0.07 to 0.7 mm, and particularly preferably 0.1 to 0.5 mm.

Before use, the aluminum plate is subjected preferably to surface treatment such as roughening treatment or anodizing treatment.

[Intermediate Layer]

An intermediate layer may be formed as needed between the crosslinked hydrophilic layer and the substrate in the planographic printing plate prepared by the method of the invention. The crosslinked hydrophilic layer serves both as an image region and a non-image region in the invention, and thus, the crosslinked hydrophilic layer is preferably tightly bonded to the substrate; and formation of the intermediate layer is advantageous in improving the adhesion between the substrate and the crosslinked hydrophilic layer.

When the substrate is a plastic film, an intermediate layer is preferably formed on the surface of the substrate by coating an acrylic, urethane-based, cellulosic, or epoxy adhesive on the substrate; or alternatively, by coating one of the undercoat layers described in JP-A Nos. 6-316183, 8-272088, 9-179311, and 2001-199175, that is an intermediate layer containing a homopolymer or copolymer of polyvinyalcohol or hydroxyalkyl acrylate or methacrylate, and hydrolyzed tetraethyl or tetramethyl orthosilicate, and favorably, additionally particles of silicon dioxide and/or titanium dioxide may be formed on the surface of the substrate.

Alternatively, when a metal substrate is used, use of an organic or inorganic resin is preferable. The organic or inorganic resin may be selected from a wide range of known hydrophobic polymers, hydrophilic polymers, and crosslinked hydrophilic polymers and inorganic polymers including sol-gel converting compounds such as hydroxyl or alkoxy group-containing aluminum, silicon, titanium, and zirconium, and the like. The preferable intermediate layer in the invention is an intermediate layer containing silica.

A hydrophilic polymer binder may be added as needed to the intermediate layer. Typical examples of the hydrophilic polymer binders include polyvinylalcohol (PVA), modified PVAs such as carboxy-modified PVA, starch and the derivatives thereof, cellulose derivatives such as carboxymethylcellulose and hydroxyethylcellulose, casein, gelatin, polyvinylpyrrolidone, vinyl acetate-crotonic acid copolymers, styrene-maleic acid copolymers, polyacrylic acid and the salts thereof, polyacrylamide, water-soluble acrylic copolymers containing a water-soluble acrylic monomer such as acrylic acid or acrylamide as a main component, and the like.

When the intermediate layer contains silica, the ratio of the hydrophilic polymer binder to silica in the intermediate layer is less than 1 based on the weight. The lower limit of the ratio is not so important, but is preferably at least 0.2. The weight ratio of the hydrophilic polymer binder to silica is still more preferably 0.25 to 0.5.

The amount of the intermediate layer coated is preferably 10 mg/m² to 5,000 mg/m², and still more preferably 50 mg/M² to 3000 mg/m².

The intermediate layer composition may be coated as an aqueous colloid dispersion in the presence of a surfactant.

[Other Layers]

A back coat is formed as needed on the rear face of the substrate. Coating layers comprising the metal oxides formed by hydrolysis and polycondensation of the organic polymer compounds described in JP-A No. 5-45885 and the organic or inorganic metal compounds described in JP-A No. 6-35174 are favorably used as the back coat. Among these coating layers, alkoxysilicon compounds such as Si(OCH₃)₄, Si(OC₂H₅)₄, Si(OC₃H₇)₄, and Si(OC₄H₉)₄ are particularly preferable, because they are inexpensive and easily available, and the metal oxide coating layers obtained therefrom are superior in hydrophilicity.

[Step of Forming a Hydrophobic Image by Ejecting an Inkjet Composition and by Hardening the Inkjet Composition Using Heat or Light (Hydrophobic Region-Forming Step)]

A planographic printing plate can be obtained by ejecting an inkjet composition (C) on the surface of the crosslinked hydrophilic layer and by hardening the inkjet composition by heat or light to form a hydrophobic image. Hereinafter, the hydrophobic region-forming step will be described.

An inkjet composition (C) for use in the method of producing a planographic printing plate using an inkjet recoding process in the present invention will be described. The inkjet composition (C) is a composition that characteristically hardens by application of energy such as light or heat, and contains a polymerization-initiating system (C-1), a polymerizable compound (C-2), and various additives as needed.

(C-1) Polymerization-Initiating System

The polymerization-initiating system (C-1) in the invention contains a polymerization initiator (C-1-1) and a sensitizing dye (C-1-2).

(C-1-1) Polymerization Initiator

The radical- or cationic polymerization initiator used in the inkjet composition for forming the hydrophobic region in the invention will be described.

The polymerization initiator in the invention is a compound that generates at least one species of radical, acid and base in the chemical change caused by the action of light or the interaction with the electronically excited state of sensitizing dye.

Any one of common polymerization initiators known in the art may be used, and typical examples thereof are described optionally in Bruce M. Monroe et al., Chemical Revue, 93, 435 (1993); R. S. Davidson, Journal of Photochemistry and biology A: Chemistry, 73. 81 (1993); J. P. Faussier, “Photoinitiated Polymerization—Theory and Applications”: Rapra Review vol. 9, Report, Rapra Technology (1998); and M. Tsunooka et al., Prog. Polym. Sci., 21, 1 (1996). Many compounds favorably used in chemical-amplification photoresists and for photocationic polymerization are also described in Japanese Research Association for Organic Electronics Materials Ed., “Organic Materials for Imaging” (published by Bun-Shin Shuppan (1993), pp. 187 to 192). Also known are the compounds that cause oxidative or reductive bond cleavage by interaction with the electronically excited state of sensitizing dye, for example, described in F. D. Saeva, Topics in Current Chemistry, 156, 59 (1990); G. G. Maslak, Topics in Current Chemistry, 168, 1 (1993); H. B. Shuster et al., JACS, 112, 6329 (1990); I. D. F. Eaton et al., JACS, 102, 3298 (1980); and others.

Preferable polymerization initiators include (a) aromatic ketones, (b) aromatic onium salt compounds, (c) organic peroxides, (d) hexaarylbiimidazole compounds, (e) ketoxime ester compounds, (f) borate compounds, (g) azinium compounds, (b) metallocene compounds, (i) active ester compounds, (j) carbon-halogen bond-containing compounds, and the like.

Preferable examples of the aromatic ketones (a) include the compounds having a benzophenone or thioxanthone skeleton described in “Radiation Curing in Polymer Science and Technology” J. P. Fouassier and J. F. Rabek (1993), pp. 77 to 117, and the like. More preferable examples of the aromatic ketones (a) include the α-thiobenzophenone compounds described in Japanese Patent Application Publication (JP-B) No. 47-6416; the benzoin ether compounds described in JP-B No. 47-3981; the α-substituted benzoin compounds described in JP-B No. 47-22326; the benzoin derivatives described in JP-B No. 47-23664; the aroylphosphonic acid esters described in JP-A No. 57-30704; the dialkoxybenzophenones described in JP-B No. 60-26483; the benzoin ethers described in JP-B No. 60-26403 and JP-A No. 62-81345; the a-aminobenzophenones described in JP-B No. 1-34242, U.S. Pat. No. 4,318,791, and E.P. No. 0284561 A1; p-di(dimethylaminobenzoyl)benzenes described in JP-A No. 2-211452; the thio-substituted aromatic ketones described in JP-A No. 61-194062; the acylphosphine sulfides described in JP-B No. 2-9597; the acylphosphines described in JP-B No. 2-9596; the thioxanthones described in JP-B No. 63-61950; the coumarins described in JP-B No. 59-42864; and the like.

Examples of the aromatic onium salt compounds (b) include aromatic onium salts of the elements in Groups V, VI or VII in the periodic table, specifically, those of N, P, As, Sb, Bi, O, S, Se, Te, or I. Favorable examples thereof include the iodonium salts described in EP No. 104143, U.S. Pat. No. 4,837,124, and JP-A Nos. 2-150848 and 2-96514; the sulfonium salts described in EP Nos. 370693, 233567, 297443, 297442, 279210, and 422570, and U.S. Pat. Nos. 3,902,144, 4,933,377, 4,760,013, 4,734,444, and 2,833,827; diazonium salts (benzene diazonium salts that may be substituted, and the like); diazonium salt resins (formaldehyde resins of diazodiphenylamine, and the like); N-alkoxypyridinium salts (e.g., those described in U.S. Pat. No. 4,743,528, JP-A Nos. 63-138345, 63-142345, and 63-142346, and JP-B No. 46-42363, specifically, 1-methoxy-4-phenylpyridinium tetrafluoroborate, and the like), and the compounds described in JP-B Nos. 52-147277, 52-14278, and 52-14279. The aromatic onium salt compounds (b) generate a radical or an acid as active species.

Examples of the organic peroxides (c) include almost all organic compounds having one or more oxygen-oxygen bonds in the molecule; and favorable examples thereof include peroxidated esters such as 3,3′,4,4′-tetra-(t-butylperoxycarbonyl)benzophenone, 3,3′,4,4′-tetra-(t-amylperoxycarbonyl)benzophenone, 3,3′,4,4′-tetra-(t-hexylperoxycarbonyl)benzophenone, 3,3′,4,4′-tetra-(t-octylperoxycarbonyl)benzophenone, 3,3′,4,4′-tetra-(cumylperoxycarbonyl)benzophenone, 3,3′,4,4+-tetra-(p-isopropyl cumylperoxycarbonyl)benzophenone, and di-t-butyl diperoxyisophthalate.

Examples of the hexaarylbiimidazole compounds (d) include the Rofin dimers described in JP-B Nos. 45-37377 and 44-86516, such as 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methyl phenyl)-4,4′,5,5′-tetraphenylbiimidazole, 2,2′-bis(o-trifluorophenyl)-4,4′,5,5′-tetraphenylbiimidazole, and the like.

Examples of the ketoxime ester compounds (e) include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-p-toluenesulfonyloxyiminobutan-2-one, 2-ethoxycarbonyloxyimino-1-phenylpropan-1-one, and the like.

Examples of the borate compounds (f), other examples of the polymerization initiators in the invention, include the compounds described in U.S. Pat. Nos. 3,567,453 and 4,343,891 and E.P. Nos. 109,772 and 109,773.

Examples of the azinium salt compounds (g), other examples of the polymerization initiators, include the compounds having an N—O bond described in JP-A Nos. 63-138345, 63-142345, 63-142346, and 63-143537, and JP-B No. 46-42363.

Examples of the metallocene compounds (h), other examples of the polymerization initiators, include the titanocene compounds described in JP-A Nos. 59-152396, 61-151197, 63-41484, 2-249, and 2-4705 and the iron-arene complexes described in JP-A Nos. 1-304453 and 1-152109.

Typical examples of the titanocene compounds include di-cyclopentadienyl-Ti-di-chloride, di-cyclopentadienyl-Ti-bis-phenyl, di-cyclopentadienyl-Ti-bis-2,3,4,5,6-pentafluorophen-1-yl, di-cyclopentadienyl-Ti-bis-2,3,5,6-tetrafluorophen-1-yl, di-cyclopentadienyl-Ti-bis-2,4,6-trifluorophen-1-yl, di-cyclopentadienyl-Ti-bis-2,6-difluorophen-1-yl, di-cyclopentadienyl-Ti-bis-2,4-difluorophen-1-yl, di-methylcyclopentadienyl-Ti-bis-2,3,4,5,6-pentafluorophen-1-yl, di-methylcyclopentadienyl-Ti-bis-2,3,5,6-tetrafluorophen-1-yl, di-methylcyclopentadienyl-Ti-bis-2,4-difluorophen-1-yl, bis(cyclopentadienyl)-bis[2,6-difluoro-3-(pyr-1-yl)phenyl]titanium, bis(cyclopentadienyl)-bis[2,6-difluoro-3-(methylsulfonamido)phenyltitanium, bis(cyclopentadienyl)-bis[2,6-difluoro-3-(N-butylbiaroyl-amino)phenyl]titanium, and the like.

Examples of the active ester compounds (i) include the nitrobenzyl ester compounds described in EP Nos. 0290750, 046083, 156153, 271851, and 0388343, U.S. Pat. Nos. 3,901,710 and 4,181,531, and JP-A Nos. 60-198538 and 53-133022; the iminosulfonate compounds described in EP Nos. 0199672, 84515, 199672, 044115, and 0101122, U.S. Pat. Nos. 4,618,564, 4,371,605, and 4,431,774, and JP-A Nos. 64-18143, 2-245756, and 4-365048; the compounds described in JP-B Nos. 62-6223 and 63-14340 and JP-A No. 59-174831; and the like.

Favorable examples of the carbon-halogen bond-containing compounds (j) include the compounds described in Wakabayashi et al., Bull. Chem. Soc, Japan, 42, 2924 (1969); the compounds described in British Patent 1388492; the compounds described in JP-A No. 53-133428; the compounds described in German Patent 3337024; and the like.

Also included are the compounds described in F. C, Schaefer et al., J. Org. Chem. 29, 1527 (1964); the compounds described in JP-A No. 62-58241; the compounds described in JP-A No. 5-281728; as well as the compounds described in German Patent No. 2641100; the compounds described in German Patent No. 3333450; the compounds described in German Patent No. 3021590; the compounds described in German Patent No. 3021599; and the like.

Preferable typical examples of the compounds represented by (a) to (j) are listed below:

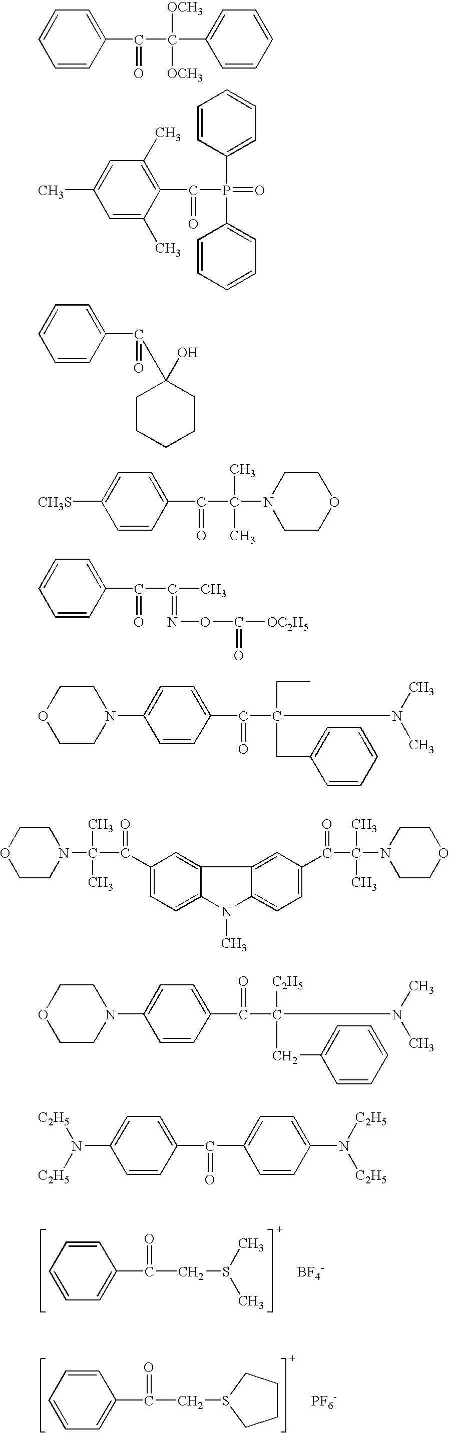

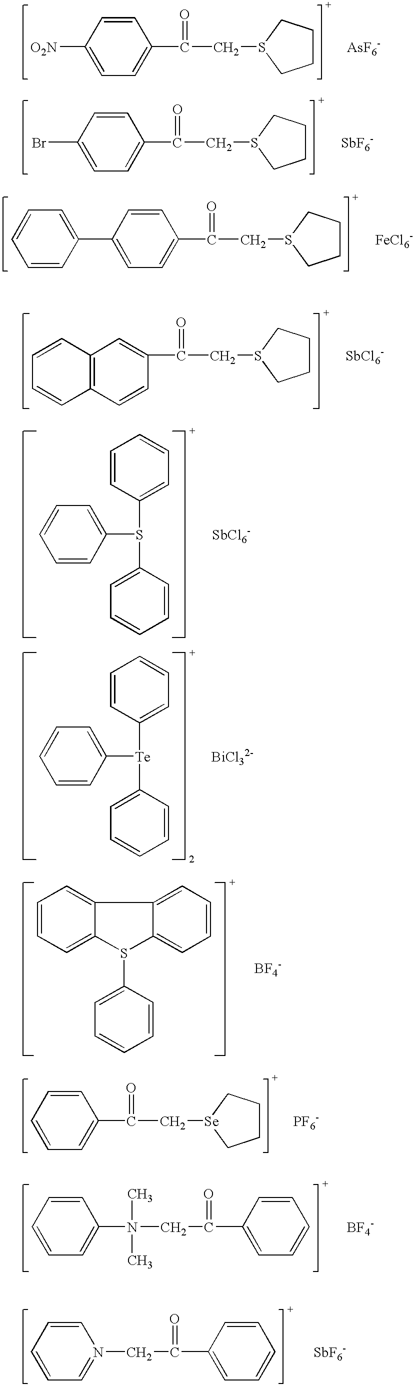

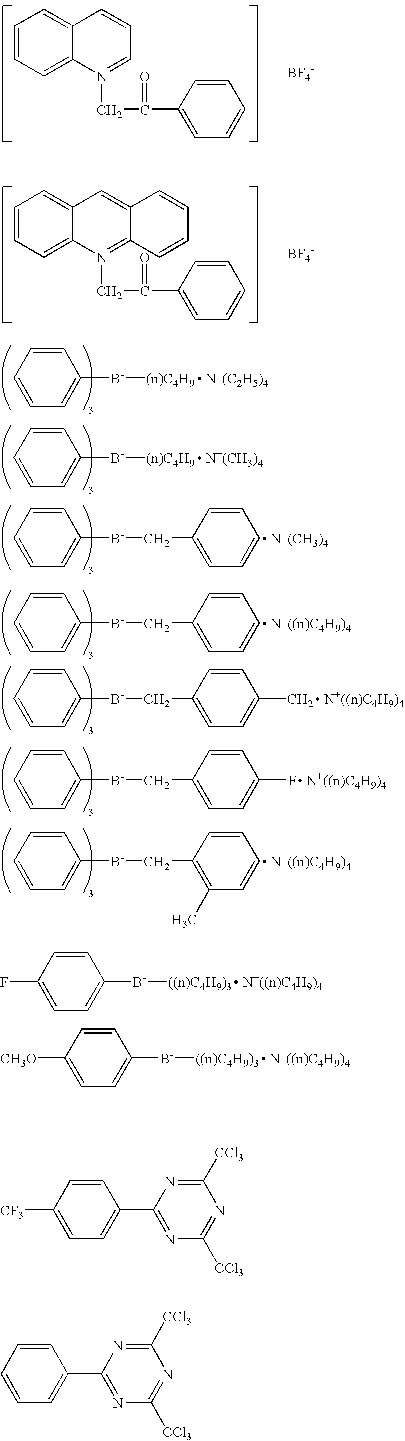

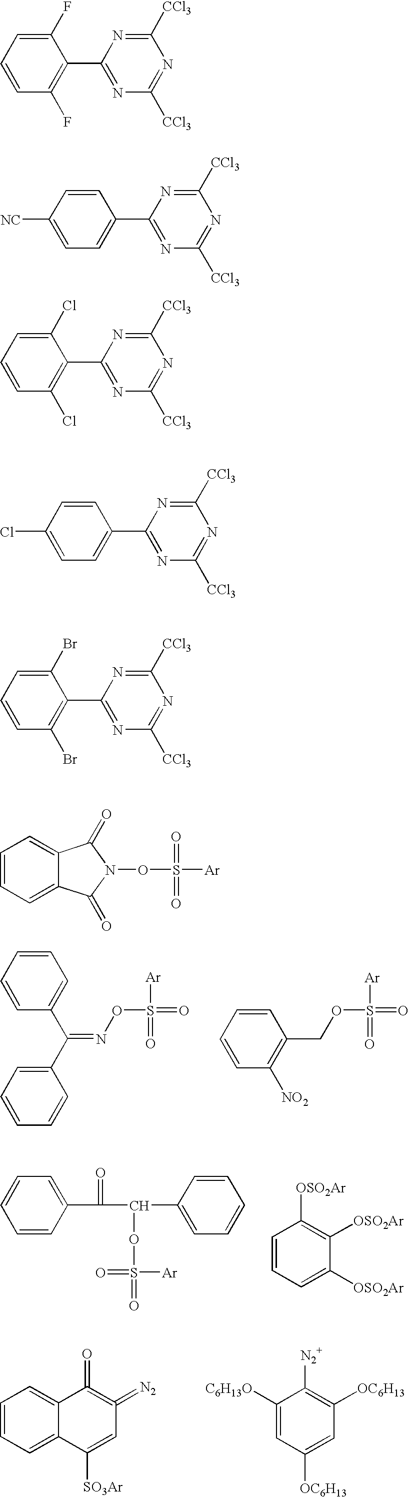

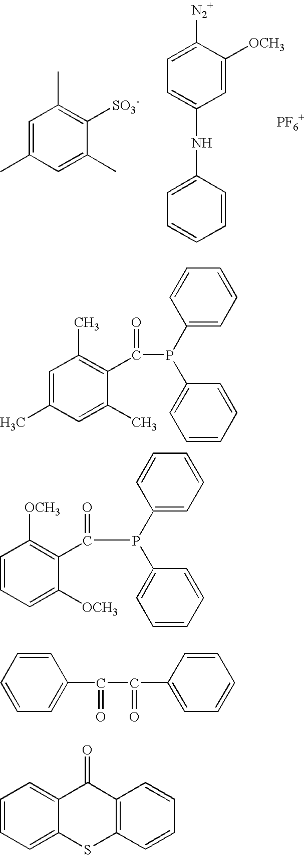

The polymerization initiators in the invention may be favorably used alone or two or more of the polymerization initiators may be used in combination. The polymerization initiator is contained in the inkjet composition in an amount of 0.01 to 20 parts by weight, preferably, 0.5 to 10 parts by weight, relative to 100 parts by weight of the polymerizable compound described below. Further, the polymerization initiator in the invention is preferably contained in the inkjet composition at a weight ratio of polymerization initiator:sensitizing dye of 200:1 to 1:200, preferably, 50:1 to 1:50, and more preferably, 20:1 to 1:5, relative to the sensitizing dye described below.

(C-1-2) Sensitizing Dye

In the invention, a sensitizing dye (C-1-2) may be added to the inkjet composition for forming the hydrophobic region, in order to improve sensitivity of the polymerization initiator. Addition of the sensitizing dye is preferable, in particular for acceleration of the decomposition of the radical polymerization initiator and increase in the amount of radicals generated. Preferable examples of the sensitizing dye include dyes having an absorption band at the wavelength of 350 to 450 nm and belonging to the following compounds:

Polynuclear aromatic compounds (e.g., pyrene, perylene, and triphenylene), xanthenes (e.g., fluorescein, eosin, erythrocin, rhodamine B, and rose bengal), cyanines (e.g., thiacarbocyanine and oxacarbocyanine), merocyanines (e.g., merocyanine and carbomerocyanine), thiazines (e.g., thionine, methylene blue, and toluidine blue), acridines (e.g., acridine orange, chloroflavine, and acriflavine), anthraquinones (e.g., anthraquinone), squaliums (e.g., squalium), and coumarins (e.g., 7-diethylamino-4-methylcoumarin).

More preferable examples of the sensitizing dyes include the compounds represented by the following Formulae (IX) to (XIII).

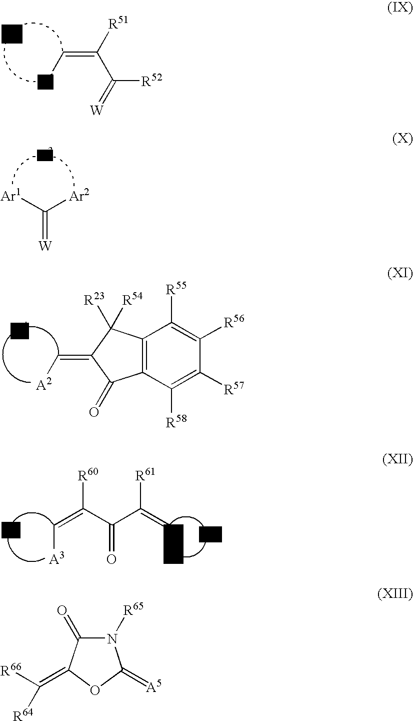

In Formula (IX), A1 represents a sulfur atom or NR⁵⁰; R⁵⁰ represents an alkyl or aryl group; L² represents a non-metal atom group that forms a basic nucleus of the dye, together with the neighboring A¹ and neighboring carbon atoms;

R⁵¹ and R⁵² each independently represent a hydrogen atom or a monovalent non-metal atom group; or R⁵¹ and R⁵² may bind to each other to form an acidic nucleus of the dye. W represents an oxygen atom or a sulfur atom.

In Formula (X), Ar¹ and Ar² each independently represent an aryl group, or they are bound to each other via the -L³-bond; L³ represents —O— or —S—; and W is the same definition as that in Formula (IX).

In Formula (XI), A² represents a sulfur atom or NR⁵⁹; L⁴ represents a non-metal atom group forming a basic nucleus of the dye together with the neighboring A² and carbon atoms; R⁵³, R⁵⁴, R⁵⁵, R⁵⁶, R⁵⁷ and R⁵⁸ each independently represent a monovalent non-metal atom group; and R⁵⁹ represents an alkyl or aryl group.

In Formula (XII), A³ and A⁴ each independently represent —S— or —NR⁶²— or —NR⁶³—; R⁶² and R⁶³ each independently represent a substituted or unsubstituted alkyl group or a substituted or unsubstituted aryl group; L⁵ and L⁶ each independently represent a non-metal atom group forming a basic nucleus of the dye together with the neighboring A³ or A⁴ and neighboring carbon atoms; R⁶⁰ and R⁶¹ each independently represent a hydrogen atom or a monovalent non-metal atom group, or may bind to each other to form an aliphatic or aromatic ring.

In Formula (XIII), R⁶⁶ represents an aromatic or heterocyclic ring that may be substituted; and A⁵ represents an oxygen or sulfur atom or —NR⁶⁷—. R⁶⁴, R⁶⁵ and R⁶⁷ each independently represent a hydrogen atom or a monovalent non-metal atom group; or R⁶⁷ and R⁶⁴, or R⁶⁵ and R⁶⁷ may bind to each other to form an aliphatic or aromatic ring.

Typical favorable examples of the compounds represented by Formulae (IX) to (XIII) are listed below. 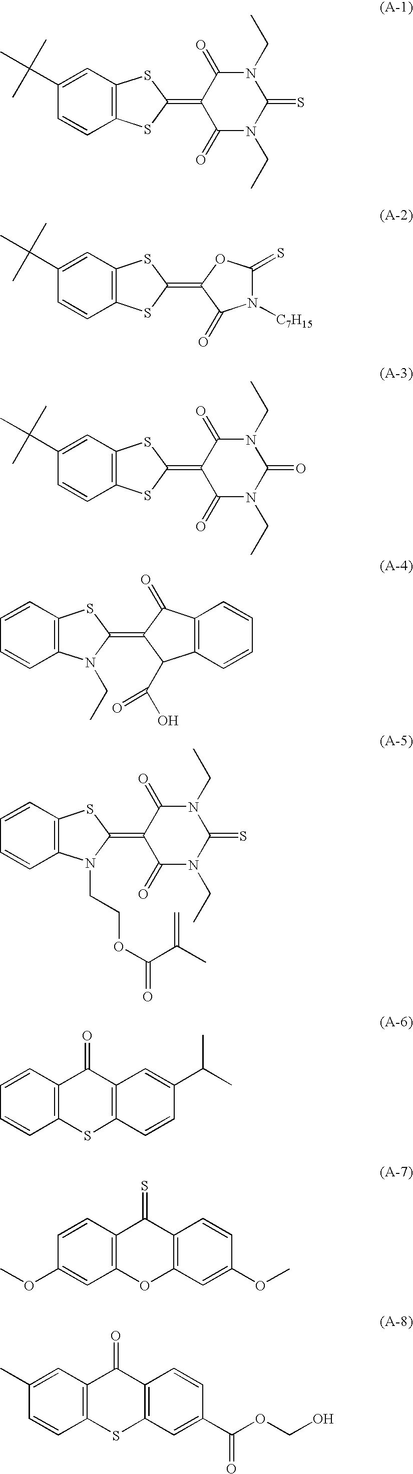 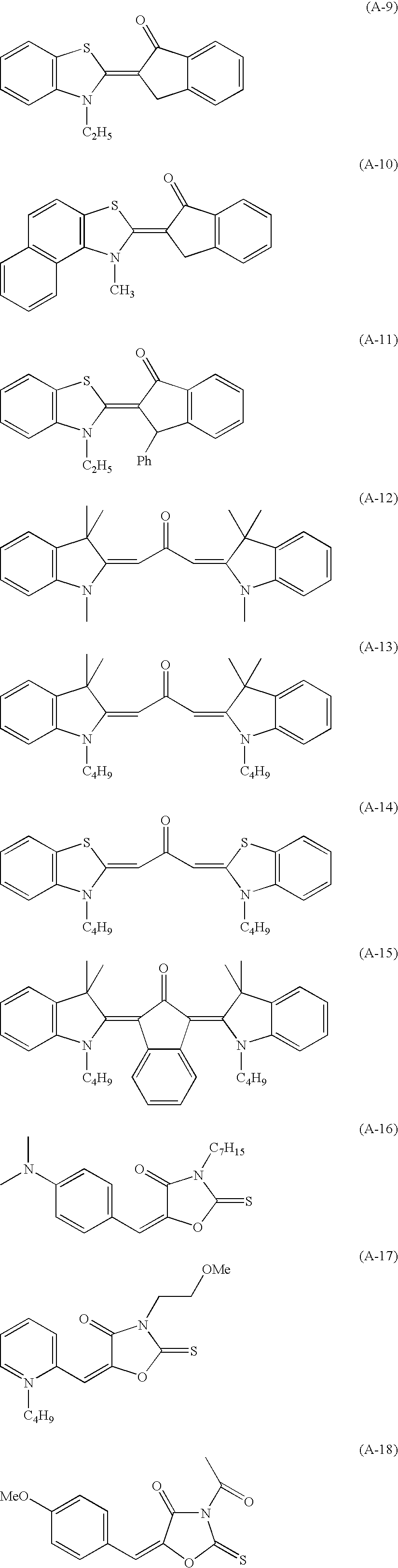 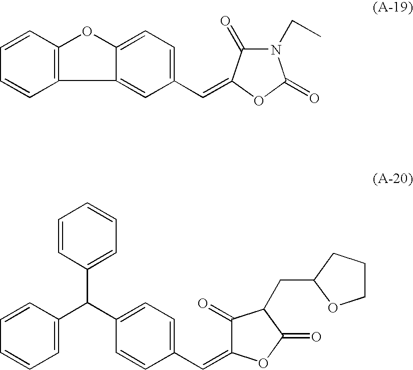
(C-1-3) Other Additives

Other additives such as co-sensitizer and chain transfer may be added as needed to the polymerization-initiating system (C) in the invention.

(C-1-3-1) Other Co-Sensitizer

Any known compounds that are effective in improving sensitivity or suppressing the polymerization inhibition due to an oxygen may be added as an other co-sensitizer.

Examples of the other co-sensitizers include amines such as the compounds described in M. R. Sander et al., “Journal of Polymer Society”, Vol. 10, p 3173 (1972), JP-B No. 44-20189, JP-A Nos. 51-82102, 52-134692, 59-138205, 60-84305, 62-18537, and 64-33104, and Research Disclosure 33825; and typical examples thereof include triethanolamine, ethyl p-dimethylaminobenzoate, p-formyldimethylaniline, p-methylthiodimethylaniline, and the like.

Other examples thereof include thiols and sulfides such as thiol compounds described in JP-A No. 53-702, JP-B No. 55-500806, and JP-A No. 5-142772, and disulfide compounds described in JP-A No. 56-75643, and the like; typical examples thereof include 2-mercaptobenzothiazole, 2-mercaptobenzoxazole, 2-mercaptobenzimidazole, 2-mercapto-4(3H)-quinazoline, β-mercaptonaphthalene, and the like.

Yet other examples include amino acid compounds (e.g., N-phenylglycine, and the like), organic metal compounds described in JP-B No. 48-42965 (e.g., tributyltin acetate, and the like), hydrogen donors described in JP-B No. 55-34414, sulfur compounds described in JP-A No. 6-308727 (e.g., trithiane, and the like), phosphorus compounds described in JP-A No. 6-250387 (diethyl phosphite, and the like), Si—H and Ge—H compounds described in Japanese Patent Application No. 6-191605, and the like.

(C-1-4) Content of Polymerization-Initiating System

In the inkjet composition in the invention, the polymerization-initiating system (C) is contained in an amount of 0.2 to 40 wt % as solid content, relative to the total solid content of the inkjet composition; and the polymerization-initiating system (C) preferably contains 0.5 to 30 wt % of a co-sensitizer, 0.5 to 40 wt %, preferably, 1.0 to 30 wt % of a polymerization initiator, 0 to 40 wt %, preferably, 1 to 30 wt % of an optional sensitizing dye, and 0 to 30 wt %, preferably, 0.5 to 20 wt % of other additives.

The inkjet composition in the invention contains the polymerization-initiating system (C-1) and a polymerizable compound (C-2), and as needed, a coloring agent (C-3) and other components (C-4).

(C-2) Polymerizable Compound

As examples of the polymerizable compounds (C-2) for use in the inkjet composition, radically polymerizable compounds such as the photocurable materials employing a photopolymerizable composition described in JP-A No. 7-159983, JP-B No. 7-31399, JP-A Nos. 8-224982 and 10-863, and Japanese Patent Application No. 7-231444, and cationically polymerizable compounds, for example, cationically polymerizable photocurable resins have been known and more recently, photocationically polymerizable photocurable resins that are sensitized by a light having a wavelength longer than the visible light are also disclosed, for example, in JP-A Nos. 6-43633 and 8-324137.

(C-2-1) Radically Polymerizable Compound

The radically polymerizable compound is a compound having a radically polymerizable, ethylenically unsaturated bond, and is not particularly limited if it has at least one radically polymerizable, ethylenically unsaturated bond. Examples of the radically polymerizable compound include compounds in various chemical forms such as monomer, oligomer, and polymer. One of the radically polymerizable compounds may be used alone or two or more of the radically polymerizable compounds may be used in combination at an optional ratio for improvement of desirable properties. A multifunctional compound having two or more functional groups is more preferable than a monofunctional compound. More preferably, two or more multifunctional compounds are used in combination, for control of the properties including reactivity and physical properties.

Examples of the polymerizable compounds having a radically polymerizable, ethylenically unsaturated bond in the invention are radically polymerizable compounds including unsaturated carboxylic acids such as acrylic acid, methacrylic acid, itaconic acid, crotonic acid, isocrotonic acid, and maleic acid, and the salts, esters, urethanes, amides, and anhydrides thereof, acrylonitrile, styrene, as well as various unsaturated polyesters, unsaturated polyethers, unsaturated polyamides, unsaturated urethanes, and the like. Typical examples thereof include acrylic acid derivatives such as 2-ethylhexyl acrylate, 2-hydroxyethyl acrylate, butoxyethyl acrylate, carbitol acrylate, cyclohexyl acrylate, tetrahydrofurfuryl acrylate, benzyl acrylate, bis(4-acryloxypolyethoxyphenyl)propane, neopentylglycol diacrylate, 1,6-hexanediol diacrylate, ethylene glycol diacrylate, diethylene glycol diacrylate, triethylene glycol diacrylate, tetraethylene glycol diacrylate, polyethylene glycol diacrylate, polypropylene glycol diacrylate, pentaerythritol triacrylate, pentaerythritol tetraacrylate, dipentaerythritol tetraacrylate, trimethylolpropane triacrylate, tetramethylolmethane tetraacrylate, oligoester acrylates, N-methylolacrylamide, diacetone acrylamide, and epoxy acrylate; and methacrylic acid derivatives such as methyl methacrylate, n-butyl methacrylate, 2-ethylhexyl methacrylate, lauryl methacrylate, allyl methacrylate, glycidyl methacrylate, benzyl methacrylate, dimethylaminomethyl methacrylate, 1,6-hexanediol dimethacrylate, ethylene glycol dimethacrylate, triethylene glycol dimethacrylate, polyethylene glycol dimethacrylate, polypropylene glycol dimethacrylate, trimethylolethane trimethacrylate, trimethylolpropane trimethacrylate, and 2,2-bis(4-methacryloxypolyethoxyphenyl)propane. In addition, derivatives of ally compounds such as allylglycidylether, diallylphtalate, triallyltrimeritate, and the like may be mentioned.

More specific examples thereof include radically polymerizable or crosslinkable monomers, oligomers or polymers commercially available or known in the art, such as those described in Shinzo Yamashita Ed., “Crosslinking Agent Handbook”, (1981, Taisei Publishing); Kiyoshi Kato Ed., “UV-EB Hardening Handbook (Raw Material)” (1985, Kobunshi Kankokai); RadTech Japan Ed., “Application and Market of UV-EB Hardening Technology”, p. 79 (1989, CMC); Eiichiro Takiyama, “Polyester Resin Handbook”, (1988, Nikkankogyo Shimbun), and others.

(C-2-2) Cationically Polymerizable Compound

Any one of various known cationically polymerizable compounds (monomer) may be used as the cationically polymerizable compound. Examples thereof include the epoxy compounds, vinylether compounds, and oxetane compounds exemplified in JP-A Nos. 6-9714, 2001-31892, 2001-40068, 2001-55507, 2001-310938, 2001-310937, and 2001-220526, and the like. Examples of the cationically polymerizable compounds in the invention include oxetane compounds, epoxy compounds, vinylether compounds, and the combinations thereof.

(C-2-3) Preferable Polymerizable Compound

The polymerizable compound favorably used in the invention is a (meth)acrylic monomer or prepolymer, an epoxy based monomer or prepolymer, an urethane based monomer or prepolymer, or the like. Favorable examples thereof include the following compounds:

2-Ethylhexyl-diglycol acrylate, 2-hydroxy-3-phenoxypropyl acrylate, 2-hydroxybutyl acrylate, hydroxypivalic acid neopentylglycol diacrylate, 2-acryloyloxyethylphthalic acid, methoxy-polyethylene glycol acrylate, tetramethylolmethane triacrylate, 2-acryloyloxyethyl-2-hydroxyethylphthalic acid, dimethyloltricyclodecane diacrylate, ethoxylated phenyl acrylates, 2-acryloyloxyethylsuccinic acid, nonylphenol EO adduct acrylates, modified glycerol triacrylates, bisphenol A diglycidylether acrylic acid adducts, modified bisphenol A diacrylates, phenoxy-polyethylene glycol acrylate, 2-acryloyloxyethylhexahydrophthalic acid, bisphenol A-PO adduct diacrylates, bisphenol A-EO adduct diacrylates, dipentaerythritol hexaacrylate, pentaerythritol triacrylate, tolylene diisocyanate urethane prepolymers, lactone-modified flexible acrylates, butoxyethyl acrylate, propylene glycol diglycidylether acrylic acid adducts, pentaerythritol triacrylate hexamethylene diisocyanate urethane prepolymers, 2-hydroxyethyl acrylate, methoxydipropylene glycol acrylate, ditrimethyrollpropane tetraacrylate, pentaerythritol triacrylate hexamethylene diisocyanate urethane prepolymers, stearyl acrylate, isoamyl acrylate, isomyristyl acrylate, isostearyl acrylate, and the like.

The acrylate compounds give an inkjet composition with less skin irritation or sensitization than polymerizable compounds hitherto conventionally used in a UV-curable ink composition. These compounds can lower a viscosity of ink composition, and can provide more reliable property during ink ejection and favorable polymerization sensitivity and adhesiveness to a recording medium. In the invention, when one of the acrylate compounds above is used as the polymerizable compound, the content of the acrylate compound is, for example, 20 to 95 wt %, preferably 50 to 95 wt %, and more preferably 70 to 95 wt %, relative to the weight of the ink composition for inkj et recording.

In the invention, the monomers exemplified above as the polymerizable compound, if low molecular weight compound, are less sensitization and have high reactivity, less viscosity, and superior in adhesiveness to the recording medium.

For further improvement in sensitivity, ink bleeding, and adhesiveness to the recording medium, combined use of the monoacrylate described above and a multifunctional acrylate monomer or multifunctional acrylate oligomer having a molecular weight of 400 or more, preferably 500 or more, is preferred. Further, combined use of a monofunctional, a bifunctional, or a trifunctional or higher multifunctional monomer is particularly preferable. It is possible to improve sensitivity, ink bleeding, and adhesiveness to the recording medium while maintaining safety. As the oligomer, an epoxy acrylate oligomer or a urethane acrylate oligomer is particularly preferred.

In forming an image on a planographic printing plate using a flexible substrate such as PET or PP film, combined use of a monoacrylate selected from the compounds above and a multifunctional acrylate monomer or multifunctional acrylate oligomer is preferable, because it gives the film flexibility, increased adhesiveness, and heightened film strength. Preferable the monoacrylate is stearyl acrylate, isoamyl acrylate, isomyristyl acrylate, or isostearyl acrylate, because it is higher in sensitivity and less shrinkage and thus results in preventing curl generation, and it is effective in preventing ink bleeding, minimizing odor of printed matter and reducing the cost of irradiation apparatus.

Methacrylates are generally less skin irritation and better strength of the harden film than acrylates.

Among the compounds above, an alkoxy acrylate is preferably used in an amount of less than 70 wt % and the balance of an acrylate is preferable for obtaining favorable sensitivity and preventing ink bleeding and odor generation.

(C-2-4) Amount of Polymerizable Compound Added

The amount of the polymerizable compound added in the invention is, for example, 1 to 97 wt %, more preferably 30 to 95 wt %, relative to the total weight of the inkjet composition.

(C-3) Coloring Agent

The inkjet composition in the invention may contain a coloring agent. Addition of a coloring agent to the composition forming a hydrophobic image region on planographic printing plate is not absolutely necessary, but is preferable, for example, from the viewpoint of plate-checking efficiency. The coloring agent is not particularly limited, but is preferably a pigment superior in weather resistance, and any one of known coloring agents such as soluble dyes, oily dyes, and the like may be used. Common pigments could not be used in conventional inkjet compositions in the past. It is because the pigments, which function as a polymerization inhibitor in the polymerization reaction, cause the problem of deterioration in hardening sensitivity. However, the polymerization-initiating system (C-1) described above generates a greater amount of active species and thus, allows use of such a coloring agent.

The coloring agent for use in the invention is not particularly limited, and examples thereof include the organic or inorganic pigments described in Color Index having the following numbers:

Red or magenta pigments such as Pigment Red 3, 5, 19, 22, 31, 38, 43, 48:1, 48:2, 48:3, 48:4, 48:5, 49:1, 53:1, 57:1, 57:2, 58:4, 63:1, 81, 81:1, 81:2, 81:3, 81:4, 88, 104, 108, 112, 122, 123, 144, 146, 149, 166, 168, 169, 170, 177, 178, 179, 184, 185, 208, 216, 226, and 257, Pigment Violet 3, 19, 23, 29, 30, 37, 50, and 88, and Pigment Orange 13, 16, 20, and 36; blue or cyan pigments such as Pigment Blue 1, 15, 15:1, 15:2, 15:3, 15:4, 15:6, 16, 17-1, 22, 27, 28, 29, 36, and 60; green pigments such as Pigment Green 7, 26, 36, and 50; yellow pigment such as Pigment Yellow 1, 3, 12, 13, 14, 17, 34, 35, 37, 55, 74, 81, 83, 93, 94, 95, 97, 108, 109, 110, 137, 138, 139, 153, 154, 155, 157, 166, 167, 168, 180, 185, and 193; black pigments such as Pigment Black 7, 28, and 26; white pigments such as Pigment White 6, 18, and 21; and the like.

After addition to the inkjet composition in the invention, it is preferred that the coloring agent is dispersed properly in the composition. Any one of dispersing machines such as ball mill, sand mill, attriter, roll mill, agitator, Henschel mixer, colloid mill, ultrasonic wave homogenizer, pearl mill, wet jet mill, and paint shaker may be used for dispersing the coloring agent.

It is also possible to add a dispersant during dispersion of the coloring agent. The dispersant is not particularly limited, but a polymer dispersant is preferably used, and examples of the polymer dispersants include, for example, Solsperse series products manufactured by Zeneca. It is also possible to use a synergist suitable for the pigment used as a dispersion aid. These dispersants and dispersion aids are preferably added in an amount of 1 to 50 parts by weight relative to 100 parts by weight of the coloring agent.

The coloring agent may be added directly into the inkjet composition, or may be added as it is previously dispersed in a solvent or a dispersion medium such as the polymerizable compound in the invention, for improvement in dispersion efficiency. Preferably, the coloring agent is added after it is first added to and blended with the polymerizable compound, in order to avoid the deterioration in solvent resistance when a solvent remains in the hardened image and the problem of VOCs (volatile organic compounds) caused by the residual solvent. A monomer lowest in viscosity is preferably selected as the polymerizable compound from the viewpoint of dispersion efficiency.

The average particle diameter of the coloring agent for use in the invention is, for example, 0.08 to 0.5 μm, preferably 0.1 to 0.45 μm, and more preferably, 0.15 to 0.4 μm. The maximum particle diameter of the coloring agent is, for example, 0.3 to 10 μm and preferably 0.3 to 3 μm. It is preferable to select the kinds of pigment, dispersant, and dispersion medium and design the conditions of dispersion and filtration, so that the maximum particle diameter falls in the range above. By controlling the particle diameter, it becomes possible to prevent clogging in head nozzles and retain favorable storage stability, transparency, and hardening sensitivity of the inkjet composition.

The coloring agent is preferably contained in an amount, for example, of 1 to 10 wt %, preferably 2 to 8 wt %, as solid content relative to the total weight of the inkjet composition.

(C-4) Other Additive

Other additives such as co-sensitizer, chain transfer, polymerization inhibitor, solvent, and cationically polimerizable monomer may be added as needed to the inkjet composition in the invention.

(C-4-1) Co-Sensitizer

The compounds described above in the polymerization-initiating system (C-1) may be used also as the co-sensitizer.

(C-4-2) Polymerization Inhibitor

A polymerization inhibitor may be added to the ink composition in the invention for improvement in storage stability. It is preferable to heat the inkjet composition at a temperature in the range of 40 to 80° C. and reduce the viscosity thereof before injection, and thus, it is also preferable to add a polymerization inhibitor for prevention of the head clogging due to thermal polymerization. The polymerization inhibitor is preferably added in an amount of 200 to 20,000 ppm relative to the total amount of the inkjet composition in the invention. Examples of the polymerization inhibitors include hydroquinone, benzoquinone, p-methoxyphenol, TEMPO, TEMPOL, Cupferron AI and the like.

(C-4-3) Solvent

When the inkjet composition for use in the invention is a radiation curable composition, the composition preferably contains no solvent, for facilitating reaction and accelerating hardening of the droplet immediately after ejection. However, a certain solvent may be contained therein, if it does not affect, for example, the hardening speed. An organic solvent or water may be used as the solvent in the invention. In particular, an organic solvent may be added for improvement in adhesiveness to the recording medium (substrate such as paper). Addition of an organic solvent having high boiling point can avoid the problem of VOCs. The amount of the organic solvent used is, for example, in the range of 0.1 to 5 wt %, preferably 0.1 to 3 wt %, relative to the total weight of the inkj et composition in the invention.

In order to prevent the deterioration in sensitivity due to the light shielding effect of the ink coloring agent, it is possible to prepare a hybrid radical/cation curable ink which contains a combination of a cationically polymerizable monomer and an initiator, or a combination of a radical polimerizable monomer and an initiator.

(C-4-4) Other Additives

In addition, other known compounds may be added as needed to the inkjet composition in the invention. For examples, a surfactant, a leveling additive, a matting agent, or a resin for adjustment of film physical properties such as polyester resin, polyurethane resin, vinyl resin, acrylic resin, rubber resin, or wax may be suitably selected and added. It is also preferable to add a tackifier that does not inhibit the polymerization, for improvement in adhesiveness to the recording medium such as polyolefin, PET, or the like. Typical examples thereof include high molecular adhesive polymers described in JP-A No. 2001-49200, p. 5 to 6 [e.g., copolymers produced by esters of (meth)acrylic acid and an alcohol having an alkyl group of 1 to 20 carbon atoms, esters of (meth)acrylic acid and an alicylic alcohol having 3 to 14 carbon atoms, and esters of (meth)acrylic acid and an aromatic alcohol having 6 to 14 carbon atoms], and low molecular adhesive resins having a polymerizable unsaturated bond, and the like.

(C-4-5) Content of Other Additives

Among the other additives, the co-sensitizer is preferably contained in an amount of 0 to 40 wt %, preferably, 1 to 30 wt %; the chain transfer is preferably contained in an amount of 0 to 40 wt %, preferably, 1 to 30 wt %; and the polymerization inhibitor is preferably contained in an amount of 0 to 40 wt %, preferably, 1 to 30 wt %, relative to the total weight of the inkjet composition in the invention.

Properties of Inkjet Composition (C)

As described above, the inkjet composition (C) in the invention contains a polymerization-initiating system (C-1), a polymerizable compound (C-2), and as needed a coloring agent (C-3) and other additives. The inkjet composition contains the coloring agent in an amount of 1 to −10 wt %, preferably, 2 to 8 wt %, the polymerizable compound in an amount of 1 to 97 wt %, preferably, 3 to 95 wt %; and the polymerization-initiating system in an amount of 0.01 to 20 wt %, preferably, 0.1 to 20 wt %, such that the total weight of respective components becomes 100 wt %.

For smoother ejection, the inkjet composition obtained preferably has a viscosity, for example, of 7 to 30 m Pa·s, preferably 7 to 20 m Pa·s at the ejection temperature of, for example, 40 to 80° C., preferably 25 to 30° C. For example, the inkjet composition has a viscosity of 35 to 500 mPa·s, preferably 35 to 200 mPa·s, at room temperature (25 to 30° C.). The inkjet composition is preferably adjusted appropriately, so that the viscosity thereof becomes in the range above. Even when a porous recording medium is used, it becomes possible to avoid penetration of ink into the recording medium and reduce the amount of unhardened monomer and odor, by setting a higher viscosity at room temperature. It is also possible to reduce the ink bleeding at the time of droplet ejection and consequently improve image quality.

The surface tension of the inkjet composition in the invention is, for example, 20 to 30 mN/m and preferably 23 to 28 mN/m. In the invention, because the inkjet composition is applied onto the surface of the crosslinked hydrophilic layer above, the surface tension thereof is preferably 20 mN/m or more from the viewpoints of ink bleeding and penetration, and 30 mN/m or less from the viewpoint of wettability.

(3) Inkjet-Recording Method and Apparatus

The inkjet-recording method and the inkjet-recording apparatus favorably used in the invention will be described below.

(3-1) Inkjet-Recording Method

In the invention, a planographic printing plate is prepared by ejecting the inkjet composition on the surface of a crosslinked hydrophilic layer formed on a substrate, hardening the composition ejected on the substrate by irradiation of radiation ray, and thus forming an image region (hydrophobic region) thereon. More specifically, the process comprises the following steps:

(a) a step of applying an inkjet composition on the surface of a crosslinked hydrophilic layer formed on a substrate;

(b) a step of irradiating the inkjet composition with a radiation to harden the composition, wherein the ray has a peak wavelength of 200 to 600 nm, preferably 300 to 450 nm, and more preferably 350 to 420 nm and has an output of 2,000 mJ/cm² or less, preferably 10 to 2,000 mJ/cm², more preferably 20 to 1,000 mJ/cm², and more preferably 50 to 800 mJ/cm²; and

(c) a step of forming an image region of the hardened inkjet composition on the surface of the crosslinked hydrophilic layer formed on a substrate.

(3-1-1) Planographic Printing Plate

The planographic printing plate has a crosslinked hydrophilic layer formed on a substrate in the first step of the invention and a hydrophobic image formed on the surface thereof. So-called PS plates having an oleophilic photosensitive resin layer formed on a hydrophilic substrate have been widely used as planographic printing plates. Such PS plates have been produced commonly by subjecting a mask exposure (surface exposure) of the photosensitive layer through a lith film and by dissolving and thus removing the non-image regions thereof. In recent years, digital technology, by which image information is processed, stored, and outputted electronically by computer, is becoming more and more popular. Accordingly, various newer image-output methods compatible with the digital technology have been commercialized. As a result, there is an urgent need for the “computer to plate (CTP) technology” that allows direct production of printing plates by scanning a high-directivity light such as laser beam according to digitalized image information without using the lith film, and thus the planographic printing plate that are compatible with the CTP technology.

In the invention, a method of preparing planographic printing plate in inkjet-recording process is used as the method enabling the scanning exposure of planographic printing plate.

Used in the invention is a method of producing a planographic printing plate having a desired image (hydrophobic region), by forming a crosslinked hydrophilic layer superior in hydrophilicity and durability on a substrate, ejecting an inkjet composition in an inkjet-recording process on the surface of the crosslinked hydrophilic layer superior in hydrophilicity and durability, and hardening the region of the inkjet composition by exposing it to radiation ray.

(3-1-2) Step of Ejecting an Inkjet Composition on the Surface of Crosslinked Hydrophilic Layer

When the inkjet composition in the invention is ejected onto the surface of the crosslinked hydrophilic layer, the inkjet composition is preferably ejected after it is heated to 40 to 80° C., preferably 25 to 30° C., and the viscosity of the ink is reduced to 7 to 30 m Pa·s, preferably 7 to 20 m Pa·s. In particular, use of an ink composition having a viscosity of 35 to 500 m Pa·s at 25° C. is highly effective. This method can realize high stability on the ejection. Radiation curable compositions including the inkjet composition in the invention normally have a viscosity higher than that of aqueous inks for use as an ink-jet recording ink, and thus, the viscosity thereof varies significantly depending on the fluctuation of temperature in printing. The fluctuation of the viscosity in the inkjet composition exerts a great influence on droplet size and droplet ejection speed, and consequently results in deterioration in image quality. Accordingly, it is needed to maintain the temperature of inkjet composition during printing as steady as possible. For that reason, the temperature is preferably controlled in the range of set temperature ±5° C., preferably set temperature ±2° C., and more preferably set temperature ±1° C.

(3-1-3) Step of Hardening Inkjet Composition by Irradiating it With Radiation Ray After Ejection of Inkjet Composition

The inkjet composition ejected on the surface of the crosslinked hydrophilic layer on the substrate is then hardened by irradiation with radiation ray. It is because the polymerization initiator in the polymerization-initiating system contained in the inkjet composition is decomposed by the aid of the co-sensitizer in the invention, leading to hardening of the polymerizable compound in radical polymerization.

Examples of the radiation rays for use in the invention include α-ray, γ-ray, electron beam, X-Ray, ultraviolet ray, visible or infrared light, and the like. The wavelength of the radiation ray is, for example, 200 to 600 nm, preferably, 300 to 450 nm, and more preferably, 350 to 450 nm. The polymerization-initiating system in the invention has sufficiently high sensitivity even to a low-output radiation ray. Thus, the output of the radiation ray is, for example, 10 to 2,000 mJ/cm², preferably, 20 to 1,000 mJ/cm², and more preferably, 50 to 800 mJ/cm². In addition, the exposed-plane illuminance by the radiation ray is, for example, 10 to 2,000 mW/cm² and preferably 20 to 1,000 mW/cm².

The inkjet composition in the invention is preferably exposed to such a radiation ray, for example, for 0.01 to 120 seconds and preferably for 0.1 to 90 seconds.

Conditions and basic methods of irradiating radiation ray are described in JP-A No. 60-132767. Specifically, the exposure is performed in a so-called shuttle process, i.e., by scanning a head unit and light sources, which are placed at both sides of the head unit in the ink-ejecting device. The radiation ray is irradiated after a given period (e.g., 0.01 to 0.5 second, preferably, 0.01 to 0.3 second, more preferably, 0.01 to 0.15 second) from ink ejection. It is possible to prevent bleeding of the ink ejected on the recording medium before hardening by controlling the period from ink ejection as short as possible. In this manner, it becomes possible to irradiate the ink before penetration into the depth to which no light is penetrable even on a porous recording medium, suppress retention of the unreacted monomer, and consequently reduce odor.

Alternatively, the ink composition may be hardened with a light from another light source, which is not driven. WO 99/54415 discloses, as the irradiation method, a method of using optical fiber and a method of irradiating the recording area with a collimated UV ray, i.e., a collimated light reflected from a mirror placed on the side wall of head unit.

By employing the inkjet-recording method described above, it becomes possible to control the dot diameter of the ink spotted on the surface of the crosslinked hydrophilic layer obtained in the invention to remain the dot diameter constant and thus improve image quality. When the ink composition is ejected multiple times, the ink composition may be expose to light after completion of all ink injections, but is preferably exposed to light after each ejection for acceleration of hardening.

In the invention, an inkjet composition is hardened with radiation ray and a hydrophobic image region is formed on the surface of the crosslinked hydrophilic layer in this manner.

(3-2) Inkjet-Recording Apparatus

The inkjet-recording apparatus for use in the invention is not particularly limited, and any one of commercially available inkjet-recording apparatuses may be used. That is, in the invention, an image may be recorded on a recording medium by using a commercially available inkjet-recording apparatus.

The inkjet-recording apparatus in the invention has, for example, an ink-supplying system, a temperature sensor, and a radiation ray source.

The ink-supplying system further has, for example, a stock tank for storing an inkjet composition, a supplying pipe, an inkjet composition-supplying tank immediately before the inkjet head, a filter, and a piezoelectric inkjet head. The piezoelectric inkjet head allows ejection of multi-sized dots in an amount of 1 to 100 pl, preferably, 8 to 30 pl, at a resolution, for example, of 320×320 to 4,000×4,000 dpi, preferably, 400×400 to 1,600×1,600 dpi, more preferably 720×720 dpi. The “dpi” in the invention means the dot number per 2.54 cm.

As described above, the droplet of the radiation curable inkjet composition ejected is preferably heated to a particular constant temperature, and thus, the region from the inkjet composition-supplying tank to the inkjet head is preferably insulated and heated. The method of controlling temperature is not particularly limited, and, for example, the piping units are preferably heated for control of the temperature properly according to the flow of inkjet composition and environment temperature while monitored by respective temperature sensors which are placed respectively on the respective piping units. The temperature sensors may be placed near the inkjet composition-supplying tank and inkjet head nozzle. In addition, the heating head unit is preferably, thermally insulated or protected, in order not to affect the environmental influence on the apparatus from outside temperature. It is preferable to insulate the head unit from other units and reduce the heat capacity of the entire heating unit, for shortening the start-up time needed for heating or for reducing the loss in heat energy.

Mercury lamps, gas or solid state lasers and the like have been widely used as active radiation ray sources, and mercury lamps and metal halide lamps are widely used in ultraviolet ray curable inkjet printers. However, under the current urgent need for mercury-free devices from the viewpoint of environmental protection, substitution thereof with a GaN semiconductor ultraviolet ray-emitting device is very useful industrially or environmentally. In addition, LED's (UV-LEDs) and LD's (UV-LDs) are smaller in size, longer in lifetime, higher in efficiency and lower in cost, and thus, attracting attention as a light source for radiation curable inkjet printers.

A light-emitting diode (LED) or a laser diode (LD) may be used as the active radiation ray source. In particular, an ultraviolet LED or an ultraviolet LD may be used if an ultraviolet ray source is desirable. For example, a purple LED emitting a light having the main emission spectrum at a wavelength of 365 to 420 nm is available from Nichia Corporation. If a light having a further shorter wavelength is desirable, U.S. Pat. No. 6,084,250 discloses a LED emitting a radiation ray mainly in the wavelength region of 300 to 370 nm. Alternatively, other ultraviolet LED's are also commercially available, and thus, it is possible to irradiate radiation rays different in the ultraviolet ray band. The radiation ray sources most preferable in the invention are UV-LED's, and particularly preferable are UV-LED's having a peak wavelength in the range of 350 to 420 nm.

The planographic printing plate thus prepared according to the production method of the invention, which has a hydrophilic non-image region of a crosslinked hydrophilic layer superior in hydrophilicity and durability, is resistant to staining in the non-image region and superior in ink repellency. In the inkjet-recording process, it is also possible to form an image region (hydrophobic region) suitable for the resolution of inkjet-recording apparatus in easier steps.

Hereinafter, the present invention will be described with reference to examples but is not limited thereto.

### EXAMPLES

1. Preparative Examples of Hydrophilic Polymers Having a Crosslinkable Group at One Terminal (Preparative Example 1: Preparation of Hydrophilic Polymer CA-1 Having a Terminal Carboxylic Acid)

Potassium 3-sulfopropyl methacrylate (147.8 g), mercaptopropionic acid (3.82 g), and a polymerization initiator VA-044 (0.582 g; manufactured by Wako Pure Chemical Industries) were dissolved in water (151.5 g); and the aqueous solution obtained was added dropwise under nitrogen atmosphere into water (151.5 g) kept at 50° C. over a period of 2 hours; and the mixture was then stirred additionally at 50° C. for 2 hours and at 60° C. for 2 hours, then cooled, and added dropwise gradually into acetone (4.5 L), to give a white solid precipitate. The solid obtained was filtered and dried, to give a polymer CA-1 (145 g). The acid value thereof after drying was 0.086 meq/g.

### Preparative Example 2

### Preparation of Hydrophilic Polymer CA-3 Having a Terminal Carboxylic Acid

Acrylamide (30 g) and 3-mercaptopropionic acid (3.8 g) were dissolved in ethanol (70 g); the mixture was heated to 60° C. under nitrogen atmosphere; a thermal polymerization initiator 2,2-azobisisobutylonitrile (AIBN) (300 mg) was added thereto; and the mixture was allowed to react for 6 hours. Thereafter, the resultant white precipitate was filtered and washed thoroughly with methanol, to give polymer CA-3 having a carboxylic acid at a terminal (30.8 g, acid value: 0.787 meq/g, molecular weight: 1.29×10³).

### Preparative Example 3

### Preparation of Amide Macromonomer

Acrylamide (30 g) and 3-mercaptopropionic acid (3.8 g) were dissolved in ethanol (70 g); the mixture was heated to 60° C. under nitrogen atmosphere; a thermal polymerization initiator 2,2-azobisisobutylonitrile (AIBN, 300 mg) was added; and the mixture was allowed to react for 6 hours. Thereafter, the resultant white precipitate was filtered and washed thoroughly with methanol, to give prepolymer having a carboxylic acid at a terminal (30.8 g, acid value: 0.787 meq/g, molecular weight: 1.29×10³). The prepolymer obtained (20 g) was dissolved in dimethylsulfoxide (62 g), to which glycidyl methacrylate (6.71 g), N,N-dimethyldodecylamine (catalyst, 504 mg), and hydroquinone (polymerization inhibitor, 62.4 mg) were added, and the mixture was allowed to react under nitrogen atmosphere at 140° C. for 7 hours. The reaction solution was poured into acetone, and the resulting polymer precipitate was washed thoroughly, to give a terminal-methacrylate acrylamide macromonomer (A-1) (23.4 g, weight average molecular weight: 1,400). Introduction of the polymerizable group at a terminal was confirmed from a presence of the olefin peaks of methacryloyl group at 6.12 and 5.70 ppm in ¹H-NMR-NMR (D₂O) and decrease of the acid value (0.057 meq/g).

### Preparative Example 4

### Preparation of Sulfonic Acid Macromonomer

Potassium 3-sulfopropyl methacrylate (147.8 g), mercaptopropionic acid (3.82 g) and a polymerization initiator VA-044 (0.582 g; manufactured by Wako Pure Chemical Industries) were dissolved in water (151.5 g); and the aqueous solution obtained was added dropwise under nitrogen atmosphere, to water (151.5 g) kept at 50° C. over a period of 2 hours. Thereafter, the mixture was stirred at 50° C. for 2 hours and at 60° C. for 2 hours additionally. After cooling the mixture, the mixture was added dropwise into acetone (4.5 L) gradually, to give a white solid precipitate.

The solid obtained was filtered and dried, to give polymer A (145 g). The acid value thereof after drying was 0.086 meq/g.

The polymer A (80 g) was dissolved in acetone/water (½ by volume) solvent (240 g); α-bromomethyl methacrylate (6.17 g) and triethylamine (3.48 g) were added thereto; and the mixture was stirred at room temperature for 10 hours. After stirring, the mixture was added dropwise in acetone (4 L), to give a white solid precipitate. The solid obtained was filtered and dried, to give a polymer (S-1) (82 g). The acid value thereof after drying was 0.004 meq/g. Introduction of the polymerizable group at a terminal was confirmed by a presence of peaks derived from a double bond near at 6.36 and 6.90 ppm in ¹H-NMR-NMR (D₂O).

2. Preparation of a Planographic Printing Plate Precursor

(1) Preparation of a Substrate

<Aluminum Plate>

A melt of a JIS A1050 (The disclosure of which is incorporated herein by reference) aluminum alloy containing 99.5 wt % or more aluminum, 0.30 wt % Fe, 0.10 wt % Si, 0.02 wt % Ti, and 0.013 wt % Cu and having the rest portion of inevitable impurities was subjected to cleaning treatment and then cast. In this cleaning treatment, the melt was degassed to remove unnecessary gas such as hydrogen, and filtered through a ceramic tube filter. Casting was conducted using a DC casting method. After 10-mm surface layer was removed from the solidified ingot plate of 500 mm in thickness, the plate was subjected to homogenization treatment at 550° C. for 10 hours so that intermetallic compounds were not agglomerated. Then, the plate was hot-rolled at 400° C., then annealed at 500° C. for 60 seconds in a continuous annealing furnace and cold-rolled to form an aluminum rolled plate of 0.30 mm in thickness. By regulating the roughness of pressure rollers, the center line average surface roughness, Ra, after cold rolling was regulated to be 0.2 μm. Thereafter, the plate was placed in a tension leveller to improve flatness. The resulting aluminum plate was subjected to the following surface treatment.

First, the aluminum plate was degreased at 50° C. for 30 seconds in 10 wt % aqueous sodium aluminate to remove the rolling oil from the surface thereof and then neutralized with 30 wt % aqueous nitric acid at 50° C. for 30 seconds, to remove smuts therefrom.

Then, the surface of the substrate was roughened, thereby facilitating the adhesion of the substrate to an image recording layer and further, giving a non-image region to the water holding property. Specifically, the aluminum plate was subjected to electrochemical surface roughening treatment through electrolysis of the aluminum plate by passing the aluminum plate web through an aqueous solution containing 1 wt % nitric acid and 0.5 wt % aluminum nitrate (solution temperature, 45° C.), which is supplied into an indirect feeder cell, at an electricity of 240 C/dm² at the side of an anode at a current density of 20 A/dm² in an alternating waveform in the duty ratio of 1:1.

Further, the aluminum plate was etched at 35° C. for 30 seconds in 10 wt % aqueous sodium hydroxide and then neutralized with 30 wt % aqueous sulfuric acid at 50° C. for 30 seconds to remove smuts therefrom.

Thereafter, the aluminum plate was subjected to anodizing treatment to improve abrasion resistance, chemical resistance and water holding property. Specifically, the plate was subjected to electrolysis by passing the aluminum plate web through 20 wt % aqueous sulfuric acid (solution temperature, 35° C.), which is supplied into an indirect feeder cell, at a direct current of 14 A/dm², to form 2.5 g/m² anodized film thereon.

Thereafter, the surface of the substrate was subjected to silicate treatment with 1.5 wt % aqueous sodium silicate solution No. 3 at 70° C. for 15 seconds in order to secure hydrophilicity on a non-image region. The amount of Si adhered thereto was 10 mg/m².

The substrate was washed with water. The center line surface roughness, R_{a,} of the resulting substrate was 0.25 μm.

(2) Formation of a Hydrophilic Layer

The above substrate was coated by a bar with an image recording layer coating solution of which the compositon is described hereinafter and then dried in an oven at 140° C. for 10 minutes, to form a crosslinked hydrophilic layer having a coating amount of 1.4 g/m² after drying, whereby a planographic printing plate precursor 1 was obtained.

Coating Solution (1) for Crosslinked Hydrophilic Layer

| | |
|---|---|
| Water | 100 g |
| Hydrophilic polymer CA-1 having a crosslinkable group on one | 4.0 g |
| terminal | |
| crosslinker (1) shown in below | 3.0 g |
| crosslinker (2) shown in below | 1.5 g |
| Surfactant (sodium diethylhexyl sulfosuccinate) | 0.2 g |

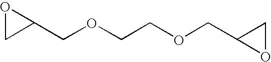

Crosslinker (1)

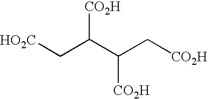

Crosslinker (2)

Planographic printing plate precursors 2 to 4 were prepared in a similar manner to the planographic printing plate precursor 1, except that the hydrophilic polymer and the crosslinker used in the coating solution (1) for crosslinked hydrophilic layer were replaced with the compounds shown in the following Table 1.

TABLE 1

| Substrate having a | Crosslinking | |
|---|---|---|
| crosslinked hydrophilic | hydrophilic | |
| layer | polymer | Crosslinker |
| Planographic printing plate | CA-1 | Crosslinker (1)/Crosslinker (2) |
| precursor 1 | | |
| Planographic printing plate | CA-1 | Crosslinker (3)/Crosslinker (4) |
| precursor 2 | | |
| Planographic printing plate | CA-3 | Crosslinker (1)/Crosslinker (4) |
| precursor 3 | | |
| Planographic printing plate | CA-3 | Crosslinker (3)/Crosslinker (2) |
| precursor 4 | | |

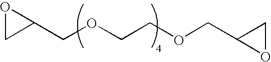

Crosslinker (3)

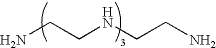

Crosslinker (4)

### Comparative Example 1

A planographic printing plate precursor C-1 were prepared in a similar manner to the planographic printing plate precursor 1, except that a crosslinked hydrophilic layer was formed with acrylic acid/acrylamide (50/50, Mw: 70,000), instead of the hydrophilic polymer CA-1 having a crosslinkable group on one terminal in the coating solution (1) for crosslinked hydrophilic layer.

(Preparation of Hydrophilic Material)

Coating solution (2) for crosslinked hydrophilic layer

| | |
|---|---|
| Polymer A-1 (obtained in Preparative Example 3 above) | 4 g |
| Ethoxylated trimethylolpropane acrylate (manufactured by | 2.7 g |
| Nippon Kayaku SR-9035) | |
| Irgacure 2959 (manufactured by Ciba-Geigy Corp.) | 0.5 g |
| Water | 100 g |

The coating solution (2) for crosslinked hydrophilic layer was applied on the aluminum plate described above such that a coating amount after drying is to be 1 g/m² and dried under heat at 120° C. for 2 minutes, to form a hydrophilic layer on the substrate.

The substrate having the hydrophilic layer was placed in a vat and the top face of the vat was sealed with Forwrap film (manufactured by Riken Technos Corp.). After substitution with nitrogen, the substrate was irradiated under a 400 w high-pressure mercury lamp (UVL-400P, manufactured by Riko Kagaku Sangyo Co., Ltd.) for 10 minutes. The obtained substrate having a hydrophilic hardened film was immersed and washed in ion-exchange water, dried at 100° C. for 1 minute, to give a planographic printing plate precursor 5 having a crosslinked hydrophilic layer formed on the surface of the substrate.

A planographic printing plate precursor 6 was prepared in a similar manner to the planographic printing plate precursor 5, except that the polymer A-1 in the coating solution (2) for crosslinked hydrophilic layer used in preparing the planographic printing plate precursor 5 was replaced with the polymer S-1 (obtained in Preparative Example 4 above).

A planographic printing plate precursor C-2 was prepared in a similar manner to the planographic printing plate precursor 5, except that the polymer A-1 in the coating solution (2) for crosslinked hydrophilic layer used in preparing the planographic printing plate precursor 5 was replaced with the following hydrophilic polymer (weight-average molecular weight:20,000). 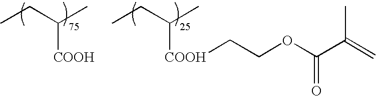
3. Formation of Image Region

Hereinafter, the method of preparing an inkjet ink will be described.

<Preparation of Coloring Agent Dispersions>

(Yellow Coloring Agent Dispersion 1)

| | |
|---|---|
| C.I. Pigment Yellow 12 | 10 parts by weight |
| Polymer dispersant (Solsperse series product | 5 parts by weight |
| manufactured by Zeneca) | |
| Stearyl acrylate | 85 parts by weight |

(Magenta Coloring Agent Dispersion 1)

| | |
|---|---|
| C.I. Pigment Red 57:11 | 5 parts by weight |
| Polymer dispersant (Solsperse series product | 5 parts by weight |
| manufactured by Zeneca) | |
| Stearyl acrylate | 80 parts by weight |

(Cyan Coloring Agent Dispersion 1)

| | |
|---|---|
| C.I. Pigment Blue 15:3 | 20 parts by weight |
| Polymer dispersant (Solsperse series product | 5 parts by weight |
| manufactured by Zeneca) | |
| Stearyl acrylate | 75 parts by weight |

(Black Coloring Agent Dispersion 1)

| | |
|---|---|
| C.I. Pigment black 7 | 20 parts by weight |
| Polymer dispersant (Solsperse series product | 5 parts by weight |
| manufactured by Zeneca) | |
| Stearyl acrylate | 75 parts by weight |

<Preparation of Ink-Jet Recording Ink>

Inkjet recording inks in various colors were prepared according to the following method, by using each of the coloring agent dispersion 1 in various color thus prepared.

(Yellow Ink 1)

| | | |
|---|---|---|
| Yellow coloring agent dispersion 1 | 20 | parts by weight |
| Stearyl acrylate | 60 | parts by weight |
| Bifunctional aromatic urethane acrylate A | 10 | parts by weight |
| (molecular weight 1,500) | | |
| Hexafunctional aromatic urethane acrylate B | 5 | parts by weight |
| (molecular weight 1,000) | | |
| Sensitizing dye A | 1 | part by weight |
| Polymerization initiator | 3 | parts by weight |
| (manufactured by Ciba Specialty Chemicals, | | |
| CGI 784) | | |
| Co-sensitizer F | 1 | part by weight |

The structures of the bifunctional aromatic urethane acrylate A (molecular weight Mw: 1,500), the hexafunctional aromatic urethane acrylate B (molecular weight Mw: 1,000), the sensitizing dye A, and the co-sensitizer F are as follows:

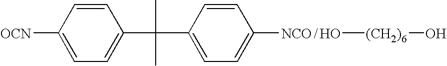

A condensate (Mw: 1,500; Bifunctional aromatic urethane acrylate A) of which the terminal is capped with

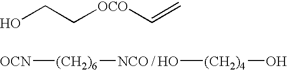

A condensate (Mw: 1,000;Hexafunctional aliphatic urethane acrylate B) of which the terminal is capped with

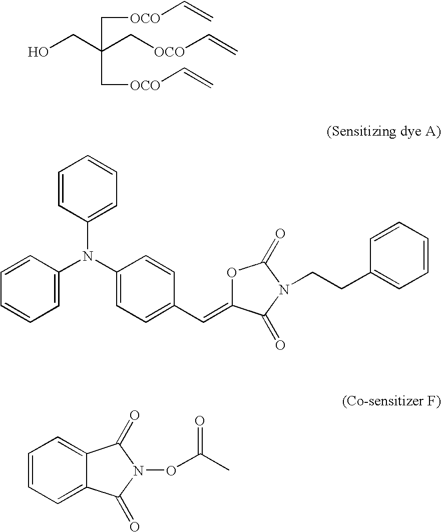

(Magenta Ink 1)

| | | |
|---|---|---|
| Magenta coloring agent dispersion 1 | 20 | parts by weight |
| Stearyl acrylate | 60 | parts by weight |
| Bifunctional aromatic urethane acrylate A | 10 | parts by weight |
| (molecular weight: 1,500) | | |
| Hexafunctional aromatic urethane acrylate B | 5 | parts by weight |
| (molecular weight: 1,000) | | |
| Sensitizing dye B | 1 | part by weight |
| Polymerization initiator (LD-1) | 3 | parts by weight |
| Co-sensitizer A | 1 | part by weight |

The structures of the sensitizing dye B, the polymerization initiator (LD-1), and the co-sensitizer A are as follows:

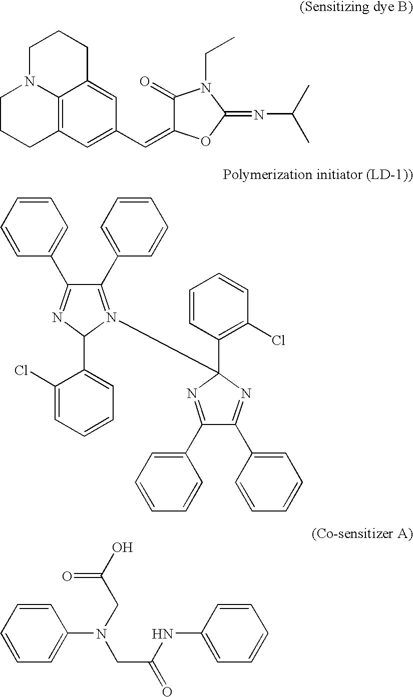

(Cyan Ink 1)

| | | |
|---|---|---|
| Cyan coloring agent dispersion 1 | 15 | parts by weight |
| Stearyl acrylate | 60 | parts by weight |
| Bifunctional aromatic urethane acrylate A | 10 | parts by weight |
| (molecular weight: 1,500) | | |
| Hexafunctional aromatic urethane acrylate B | 5 | parts by weight |
| (molecular weight: 1,000) | | |
| Sensitizing dye C | 1 | part by weight |
| Polymerization initiator A | 3 | parts by weight |
| Co-sensitizer B | 1 | part by weight |

The structures of the sensitizing dye C, the polymerization initiator A, and the co-sensitizer B are as follows:

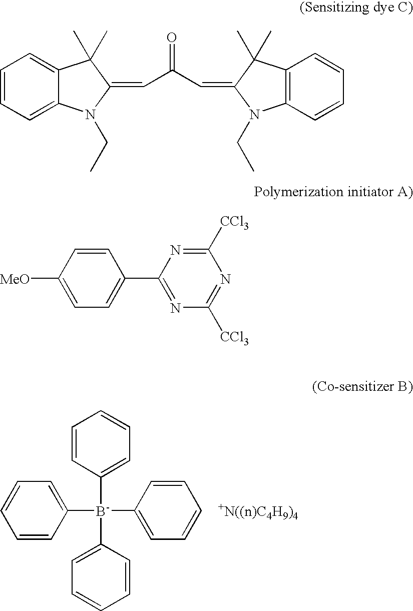

(Black Ink 1)

| | | |
|---|---|---|
| Black coloring agent dispersion 1 | 15 | parts by weight |
| Stearyl acrylate | 60 | parts by weight |
| Bifunctional aromatic urethane acrylate A | 10 | parts by weight |
| (molecular weight: 1,500) | | |
| Hexafunctional aromatic urethane acrylate B | 5 | parts by weight |
| (molecular weight: 1,000) | | |
| Sensitizing dye D | 1 | part by weight |
| Polymerization initiator | 3 | parts by weight |
| (CGI-7460, manufactured by Ciba Specialty | | |
| Chemicals) | | |
| Co-sensitizer C | 1 | part by weight |

The structures of the sensitizing dye D and the co-sensitizer C are as follows:

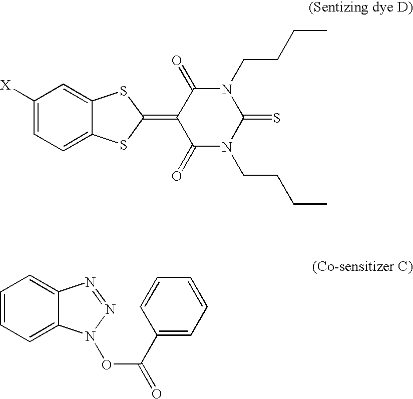

The crude inks 1 thus prepared in various colors were filtered through a filter having an absolute filtration accuracy of 2 μm, to give inks 1 in respective colors.

Each of the inkjet compositions thus prepared had an ink viscosity of 7 to 20 mPa·s at the injection temperature.

<Inkjet Image Recording>

An image was printed by using each of the ink compositions thus prepared in the Examples and Comparative Examples above. The image was printed on each of the planographic printing plates 1 to 6 obtained in Examples 1 to 6, and the planographic printing plates C-1 and C-2 obtained in Comparative Examples 1 and 2, by using a commercially available ink jet-recording apparatus having a piezoelectric inkjet nozzle, to give each of planographic printing plates of Examples 1 to 6 and Comparative Examples 1 and 2.

The inkjet composition-supplying system of the ink jet-recording apparatus has a stock tank, a supplying pipe, an ink-supplying tank immediately before inkjet head, a filter, and a piezoelectric inkjet head; and the region from the ink-supplying tank to the inkjet head was thermally insulated and heated. Temperature sensors were placed near the ink-supplying tank and inkjet head nozzle, and the temperature of nozzle region was controlled such that the nozzle region remains constant at a temperature of 70° C.±2° C. The piezoelectric inkjet head ejected 8- to 30-pl multi-sized dots at a resolution of 720×720. The exposure system, the main scanning speed, and the injection frequency were adjusted in such a manner that irradiation was started after 0.1 second from ink ejection by converging a light having a peak wavelength of 395 nm from a UV-LED light source on the recording medium at an exposed-plane illuminance of 100 mW/cm². Exposure energy was irradiated while the exposure period was made variable. The “dpi” in the invention means the dot number per 2.54 cm.

Each of the inks obtained in Examples was ejected at an environmental temperature of 25° C., and then, the UV-LED light was irradiated. The image was exposed to the light at the total exposure energy of 300 mJ/cm², until it is completely hardened when the plate feels untacky any more.

4. Evaluation of Planographic Printing Plate

Each of the planographic printing plates thus obtained in Examples 1 to 6 and Comparative Examples 1 and 2 was evaluated as follows:

(1) Background Soil

An image was printed on 500 papers, and the amount of ink deposited then in the non-image region of the print was evaluated by visual observation. The criteria for the background soil are as follows: A: without staining, and B: at least with some staining.

(2) Ink Repellency

An image was printed in a similar manner to above, and the number of papers repellent to ink was counted. A more hydrophilic layer has a smaller number of ink-repellent papers.

(3) Printing Durability

An image was printed continuously in a Heidel KOR-D printing machine until the background soil due to abrasion of the non-image region emerged, and the relative number of the papers printed was used as an indicator of printing durability (relative to 100 of Example 1). A greater numerical value indicates a higher printing durability, and is preferable. Results are summarized in Table 2.

TABLE 2

| | Substrate | | | | |
|---|---|---|---|---|---|
| | haivng a | | | | |
| | crosslinked | | Evaluation result | | |
| | hydrophilic | Inkjet | Backgroud | Ink | Printing |
| | layer | composition | soik | repellency | durability |
| Example 1 | Planographic | Cyan | A | 20 | 100 |
| | printing plate | | | | |
| | precursor 1 | | | | |
| Example 2 | Planographic | Black | A | 25 | 100 |
| | printing plate | | | | |
| | precursor 2 | | | | |
| Example 3 | Planographic | Yellow | A | 25 | 100 |
| | printing plate | | | | |
| | precursor 3 | | | | |
| Example 4 | Planographic | Black | A | 25 | 100 |
| | printing plate | | | | |
| | precursor 4 | | | | |
| Example 5 | Planographic | Black | A | 25 | 100 |
| | printing plate | | | | |
| | precursor 5 | | | | |
| Example 6 | Planographic | Magenta | A | 25 | 100 |
| | printing plate | | | | |
| | precursor 6 | | | | |
| Comparative | Planographic | Cyan | A | 75 | 90 |
| Example 1 | printing plate | | | | |
| | precursor C-1 | | | | |
| Comparative | Planographic | Black | B | 100 | unevaluated |
| Example 2 | printing plate | | | or more, | |
| | precursor C-2 | | | unevaluated | |

As apparent from Table 2, each of the planographic printing plates 1 to 6 obtained by the method of producing a planographic printing plate according to the invention was superior in the hydrophilicity and durability of the non-image region, and after formation of the image region, the printing plate allowed printing without any developing step and gave an image superior in background soil and ink repellency of the non-image region.

In the invention, although the mechanism of the crosslinked hydrophilic layer exhibiting its high hydrophilicity and high strength is still not clear, the hydrophilic layer obtained seems to become a three-dimensionally crosslinked hydrophilic layer higher in crosslinking density and strength, because the hydrophilic layer is formed by using a composition which comprises a hydrophilic polymer having a crosslinkable group at one terminal and a crosslinker and by hardening the polymer by heat. In particular, as described in the preferable embodiments of the invention, it seems to be possible to increase the crosslinking density and the durability of the hydrophilic layer further by using multiple crosslinkers different from each other.

One terminal of the hydrophilic polymer is immobilized onto the crosslinking film via chemical bond during preparation of the crosslinked hydrophilic layer in the invention, but the polymer unit having the hydrophilic unit still has an unimmobilized free group at the other terminal and has a higher degree of freedom and a structure superior in mobility. Therefore, it is possible to supply and withdraw dampening water more efficiently during printing. Further, because the three dimensionally crosslinked hydrophilic film contains a great amount of hydrophilic graft chains, allowing adsorption of a greater amount of dampening water, it is highly hydrophilic, resistant to increase in background soil, and superior in ink repellency.

In addition, because an inkjet-recording process employing a curable ink is used in forming the image region in the method according to the invention, it is not necessary to add an image forming factor to the crosslinked hydrophilic layer and it is possible to form a desirable image by using an inkjet composition having any physical properties, easily based on digital data according to the resolution of the inkjet-recording apparatus.

The invention allows easy production of a planographic printing plate superior in the hydrophilicity and durability of the non-image region and also in background soil and ink repellency of the non-image region that allows printing without any developing step after formation of the image region.

All publications, patent applications, and technical standards mentioned in this specification are herein incorporated by reference to the same extent as if each individual publication, patent application, or technical standard was specifically and individually indicated to be incorporated by reference.

What is claimed is:

1. A method of producing a planographic printing plate, comprising: forming a crosslinked hydrophilic layer on a substrate by hardening a hydrophilic polymer having a crosslinkable group at one terminal and a crosslinker using heat or light, and forming a hydrophobic image by ejecting an inkjet composition onto the formed crosslinked hydrophilic layer and by hardening the inkjet composition using heat or light.

2. The method of producing a planographic printing plate according to claim 1, wherein the hydrophilic polymer contains, on a side chain, a plurality of hydrophilic functional groups including one or more kinds of hydrophilic functional groups selected from a carboxyl group, an amino group, a phosphoric acid group, a sulfonic acid group, salts of these groups, a hydroxyl group, an amide group, a sulfonamide group, an alkoxy group, a cyano group, and a polyoxyethylene group.

3. The method of producing a planographic printing plate according to claim 1, wherein the hydrophilic polymer is a polymer having at least one heteroatom selected from oxygen, nitrogen, sulfur, or phosphorus connected to a carbon atom or carbon-carbon bond of the main chain or a polymer having, on s side chain, a plurality of hydrophilic functional groups including one or more kinds of hydrophilic functional groups selected from a carboxyl group, an amino group, a phosphoric acid group, a sulfonic acid group, salts of these groups, a hydroxyl group, an amide group, a sulfonamide group, an alkoxy group, a cyano group, and a polyoxyethylene group.

4. The method of producing a planographic printing plate according to claim 1, wherein, in forming the crosslinked hydrophilic layer, a side-chain functional group of the hydrophilic polymer is different from the terminal crosslinkable group.

5. The method of producing a planographic printing plate according to claim 1, wherein the hydrophilic polymer has a weight-average molecular weight of 1,000,000 or less.

6. The method of producing a planographic printing plate according to claim 1, wherein the hydrophilic polymer has two or more crosslinkable groups on one terminal and the crosslinkable groups are different from each other.

7. The method of producing a planographic printing plate according to claim 1, wherein a coloring agent is added to the crosslinked hydrophilic layer.

8. The method of producing a planographic printing plate according to claim 1, wherein one or more crosslinkers are used in forming the crosslinked hydrophilic layer.

9. The method of producing a planographic printing plate according to claim 8, wherein at least two crosslinkers among the multiple crosslinkers react with each other, and at least one crosslinker has a functional group that forms a covalent bond and/or an ionic bond with the hydrophilic polymer having a crosslinkable group at one terminal.

10. The method of producing a planographic printing plate according to claim 1, further comprising applying a coating solution containing the hydrophilic polymer and the crosslinker solubilized or dispersed in one or more solvents that are the same as or different from each other once or multiple times and then drying the solution.

11. The method of producing a planographic printing plate according to claim 10, wherein the drying is performed at 40° C. to 300° C.

12. The method of producing a planographic printing plate according to claim 1, wherein the inkjet composition comprises a polymerization-initiating system containing a polymerization initiator and a sensitizing dye, and polymerizable compounds containing a radically polymerizable compound and a cationically polymerizable compound.

13. The method of producing a planographic printing plate according to claim 12, wherein one or more compounds selected from the group consisting of aromatic ketones, aromatic onium salt compounds, organic peroxides, hexaarylbiimidazole compounds, ketoxime ester compounds, borate compounds, azinium compounds, metallocene compounds, active ester compounds, and compounds having a carbon-halogen bond are used as the polymerization initiator.

14. The method of producing a planographic printing plate according to claim 12, wherein a coloring agent is used in the inkjet composition.

15. The method of producing a planographic printing plate according to claim 12, wherein the content of the coloring agent in the inkjet composition is 1 to 10 wt %; that of the polymerizable compound is 1 to 97 wt %; and that of the polymerization-initiating system is 0.01 to 20 wt % based on the weight of the inkjet composition.

16. The method of producing a planographic printing plate according to claim 1, wherein the ratio of the components in the inkjet composition is adjusted such that the composition has a viscosity in the range of 7 to 30 m Pa·s.

17. The method of producing a planographic printing plate according to claim 1, wherein the surface tension of the inkjet composition is 20 to 30 mN/m.

18. The method of producing a planographic printing plate according to claim 14, wherein the content of the coloring agent in the inkjet composition is 1 to 10 wt %; that of the polymerizable compound is 1 to 97 wt %; and that of the polymerization-initiating system is 0.01 to 20 wt % based on the weight of the ink composition.
